(19) United States
(12) Patent Application Publication
(10) Pub. No.: US 2025/0365934 A1
(43) Pub. Date: Nov. 27, 2025

(54) SEMICONDUCTOR DEVICE AND METHOD OF MANUFACTURING THE SAME

(71) Applicant: SAMSUNG ELECTRONICS CO., LTD., Suwon-si (KR)

(72) Inventor: Sungjoon Park, Suwon-si (KR)

(21) Appl. No.: 19/028,883

(22) Filed: Jan. 17, 2025

(30) Foreign Application Priority Data
May 24, 2024 (KR) 10-2024-0067808

(51) Int. Cl. H10B 12/00

(52) U.S. Cl. CPC H10B 12/315; H10B 12/05

(57) ABSTRACT

A semiconductor device includes a bit line extending in a first direction on a substrate, a gate isolation insulating layer disposed on the bit line and extending in a second direction crossing the first direction and standing in a third direction, a channel layer extending along a side surface of the gate isolation insulating layer and a top surface of a bit line between the gate isolation insulating layer and an adjacent gate isolation insulating layer, a cover insulating layer configured to cover the channel layer, and a word line disposed on a side surface of the cover insulating layer above the gate isolation insulating layer. A bottom surface of the word line may not contact a top surface of the cover insulating layer disposed between the gate isolation insulating layer and an adjacent gate isolation insulating layer.

### CROSS-REFERENCE TO RELATED APPLICATION

This application claims the benefit under 35 U.S.C. § 119 to Korean Patent Application No. 10-2024-0067808, filed on May 24, 2024, in the Korean Intellectual Property Office, the entire disclosure of which is herein incorporated by reference for all purposes.

### BACKGROUND

### 1. Field of the Invention

The present disclosure relates to a semiconductor device and a method of manufacturing a semiconductor device, and more particularly, to a semiconductor device including a vertical channel transistor (VCT) and a method of manufacturing the semiconductor device.

### 2. Discussion of Related Art

The integration density of two-dimensional (2D) or planar semiconductor memory devices may be primarily determined by an area occupied by a unit memory cell, therefore the integration density may be significantly affected by a technology used for forming fine patterns. The equipment needed to increase pattern fineness may set a limitation on increasing the integration density of 2D semiconductor memory devices. Vertical channel transistors that are formed vertically on semiconductor substrates have been proposed as a replacement for planar channel transistors on semiconductor substrates.

### SUMMARY

One or more embodiments provide a semiconductor device that may effectively prevent a word line residue from being formed or left between bit lines adjacent to each other, and a method of manufacturing the semiconductor device.

The problems to be solved through the present disclosure are not limited to the above-described problems, and other problems not mentioned can be clearly understood by one of ordinary skill in the art from the following descriptions.

According to an aspect, a semiconductor device including a vertical channel transistor includes a substrate, a bit line disposed on the substrate and extending in a first direction, a gate isolation insulating layer disposed on the bit line and extending in a second direction crossing the first direction and standing in a third direction perpendicular to the substrate, a channel layer extending along a side surface of the gate isolation insulating layer and a top surface of a bit line between gate isolation insulating layer and an adjacent gate isolation insulating layer, a cover insulating layer configured to cover the channel layer, and a word line disposed on a side surface of the cover insulating layer above the gate isolation insulating layer. A bottom surface of the word line may be spaced apart from a top surface of the cover insulating layer disposed between the gate isolation insulating layer and the adjacent gate isolation insulating layer.

A top surface of a first portion of the bit line under the gate isolation insulating layer may be formed at a position higher than the bottom surface of the word line.

The top surface of the first portion of the bit line under the gate isolation insulating layer may be formed at the same position as the bottom surface of the word line.

The top surface of the first portion of the bit line under the gate isolation insulating layer may be formed at a position lower than the bottom surface of the word line and higher than the top surface of the cover insulating layer disposed between the gate isolation insulating layer and the adjacent gate isolation insulating layer.

An offset region may be formed between the bottom surface of the word line and the top surface of the cover insulating layer disposed between the gate isolation insulating layer and the adjacent gate isolation insulating layer.

An upper surface of the offset region may be formed as a horizontal surface, an inclined surface, a stepped surface, or a surface that is recessed toward the cover insulating layer.

The semiconductor device may further include a filling insulating layer disposed in a space between the gate isolation insulating layer and the adjacent gate isolation insulating layer. The filling insulating layer may be disposed in the offset region.

The gate isolation insulating layer may include a first insulating layer disposed on the bit line, and a second insulating layer disposed on the first insulating layer.

The semiconductor device may further include a data storage pattern electrically connected to the channel layer, and a landing pad disposed between the channel layer and the data storage pattern.

The semiconductor device may further include an insulating film disposed between the bit line and the substrate.

According to another aspect, a semiconductor device including a vertical channel transistor may include a substrate, a bit line disposed on the substrate and extending in a first direction, a gate isolation insulating layer disposed on the bit line and extending in a second direction crossing the first direction and standing in a third direction, a channel layer extending along a side surface of the gate isolation insulating layer and a top surface of a bit line between the gate isolation insulating layer and an adjacent gate isolation insulating layer, a cover insulating layer configured to cover the channel layer, a filling insulating layer disposed on the cover insulating layer, and a word line disposed on the filling insulating layer and a side surface of the cover insulating layer above the gate isolation insulating layer.

An offset region may be formed between a bottom surface of the word line and a top surface of the cover insulating layer disposed between the gate isolation insulating layer and the adjacent gate isolation insulating layer, and a bottom surface of the word line may be spaced apart from the top surface of the cover insulating layer disposed between the gate isolation insulating layer and the adjacent gate isolation insulating layer.

An upper surface of the offset region may be formed as a horizontal surface, an inclined surface, a stepped surface, or a surface that is recessed toward the cover insulating layer.

According to another aspect, a method of manufacturing a semiconductor device includes forming a bit line extending in a first direction on a substrate, forming a gate isolation insulating layer that extends in a second direction crossing the first direction on the bit line and that stands in a third direction perpendicular to the substrate, the gate isolation insulating layer being disposed adjacent to an adjacent gate isolation insulating layer, forming a channel layer extending along a side surface of the gate isolation insulating layer and a top surface of the bit line between the gate isolation insulating layer and the adjacent gate isolation insulating layer, forming a cover insulating layer configured to cover the channel layer, forming a sacrificial pattern layer on the cover insulating layer, forming a word line on the sacrificial pattern layer and the cover insulating layer, and removing the sacrificial pattern layer.

The forming of the sacrificial pattern layer may include forming the sacrificial pattern layer up to a same level as a top surface of the cover insulating layer that covers a second portion of the bit line outside the gate isolation insulating layer.

The forming of the bit line may include forming the bit line with a uniform thickness.

The forming of the sacrificial pattern layer may include forming the sacrificial pattern layer up to a position higher than a top surface of the cover insulating layer that covers a second portion of the bit line outside the gate isolation insulating layer.

The forming of the bit line may include forming a first portion of the bit line under the gate isolation insulating layer to be thicker than the second portion of the bit line being outside the gate isolation insulating layer.

A top surface of the bit line under the gate isolation insulating layer may be formed at a position higher than the bottom surface of the word line.

The top surface of the first portion of the bit line under the gate isolation insulating layer may be formed at the same position as the bottom surface of the word line.

The top surface of the first portion of the bit line under the gate isolation insulating layer may be formed at a position lower than the bottom surface of the word line and higher than the top surface of the cover insulating layer disposed between the gate isolation insulating layer and the adjacent gate isolation insulating layer.

The removing of the sacrificial pattern layer may include forming an offset region between a bottom surface of the word line and the top surface of the cover insulating layer disposed between the gate isolation insulating layer and the adjacent gate isolation insulating layer.

The forming of the word line may include depositing a material, and partially etching the material to form the word line on a side surface of the cover insulating layer above the gate isolation insulating layer.

The method may further include forming a filling insulating layer filling a space between the plurality of gate isolation insulating layers.

The method may further include forming a landing pad connected to the channel layer, and forming a data storage pattern connected to the landing pad.

Additional aspects of the present disclosure will be set forth in part in the description which follows and, in part, will be apparent from the description, or may be learned by practice of the disclosure.

According to embodiments, a semiconductor device and a method of manufacturing the semiconductor device may effectively inhibit or prevent a word line residue from being formed or left between bit lines adjacent to each other.

According to embodiments, a semiconductor device and a method of manufacturing the semiconductor device may effectively inhibit or prevent a word line bridge from being formed due to a word line residue formed or left between bit lines adjacent to each other.

Therefore, according to embodiments, a semiconductor device and a method of manufacturing the semiconductor device may prevent a problem from occurring in an operation of a transistor because a smooth flow of current between a source and a drain is impossible when a word line bridge is formed.

Effects according to the disclosure are not limited to those mentioned above, and other effects that have not been mentioned can be clearly understood by one of ordinary skill in the art from the following description.

### BRIEF DESCRIPTION OF THE DRAWINGS

Embodiments will be more clearly understood from the following detailed description taken in conjunction with the accompanying drawings of which:

FIG. 1A, FIG. 1B, FIG. 1C, and FIG. 1D illustrate a semiconductor device according to a related art;

FIG. 2 is a block diagram illustrating a semiconductor memory device with a semiconductor device according to an embodiment;

FIG. 3 is a circuit diagram schematically illustrating a semiconductor memory device with a semiconductor device according to an embodiment;

FIG. 4 is a layout diagram illustrating a semiconductor device according to an embodiment;

FIG. 5 is a perspective view illustrating a semiconductor device according to an embodiment;

FIG. 6 is a cross-sectional view taken along line K-K′ of FIG. 5;

FIG. 7 is a cross-sectional view taken along line M-M′ of FIG. 5;

FIG. 8 is a cross-sectional view illustrating an example of a semiconductor device according to an embodiment, taken along line K-K′ of FIG. 5;

FIG. 9 is a cross-sectional view illustrating another example of a semiconductor device according to an embodiment, taken along line K-K′ of FIG. 5;

FIG. 10 is a cross-sectional view illustrating another example of a semiconductor device according to an embodiment, taken along line K-K′ of FIG. 5;

FIG. 11 is a cross-sectional view illustrating another example of a semiconductor device according to an embodiment, taken along line K-K′ of FIG. 5;

FIG. 12 is a cross-sectional view illustrating another example of a semiconductor device according to an embodiment, taken along line K-K′ of FIG. 5;

FIG. 13 is a cross-sectional view illustrating another example of a semiconductor device according to an embodiment, taken along line K-K′ of FIG. 5;

FIG. 14 is a cross-sectional view illustrating another example of a semiconductor device according to an embodiment, taken along line K-K′ of FIG. 5;

FIG. 15 is a cross-sectional view illustrating another example of a semiconductor device according to an embodiment, taken along line K-K′ of FIG. 5;

FIG. 16 is a flowchart illustrating a method of manufacturing a semiconductor device according to an embodiment;

FIGS. 17A to 17B, FIGS. 18A to 18B, FIGS. 19A to 19B, FIGS. 20A to 20B, FIGS. 21A to 21B, FIGS. 22A to 22B, FIGS. 23A to 23B, and FIGS. 24A to 24B are cross-sectional views to describe an example of a method of manufacturing a semiconductor device; and

FIGS. 25A to 25B, FIGS. 26A to 26B, FIGS. 27A to 27B, FIGS. 28A to 28B, FIGS. 29A to 29B, FIGS. 30A to 30B, FIGS. 31A to 31B, and FIGS. 32A to 32B are cross-sectional views to describe another example of a method of manufacturing a semiconductor device.

### DETAILED DESCRIPTION

Hereinafter, embodiments will be described in detail with reference to the accompanying drawings. The disclosure allows for various changes and numerous embodiments, specific embodiments will be illustrated in the drawings and described in detail in the written description. However, this is not intended to limit embodiments to particular modes of practice, and it is to be appreciated that all changes, equivalents, and substitutes that do not depart from the spirit and technical scope of the inventive concept are encompassed by the disclosure. In the disclosure, certain detailed descriptions may be omitted when they serve to obscure the essence of the inventive concept.

The terminology used herein is for the purpose of describing particular embodiments only and is not to be limiting. The singular forms “a”, “an”, and “the” are intended to include the plural forms as well, unless the context clearly indicates otherwise. It will be further understood that the terms “comprises/including” and/or “includes/including” when used herein, specify the presence of stated features, integers, steps, operations, elements, and/or components, but do not preclude the presence or addition of one or more other features, integers, steps, operations, elements, components and/or groups thereof.

Unless otherwise defined, all terms including technical and scientific terms used herein have the same meaning as commonly understood by one of ordinary skill in the art to which embodiments belong. Terms, such as those defined in commonly used dictionaries, are to be interpreted as having a meaning that is consistent with their meaning in the context of the relevant art and the present disclosure, and are not to be interpreted in an idealized or overly formal sense unless expressly so defined herein.

Like reference numerals refer to like components and a repeated description related thereto may be omitted or simplified. In the description, detailed description of well-known related structures or functions may be omitted to support a clear and concise description.

In addition, terms such as first, second, A, B, (a), (b), and the like may be used to describe components herein. Each of these terms is not used to define an essence, order or sequence of a corresponding component but used merely to distinguish the corresponding component from other component(s). It should be noted that if it is described in the specification that one component is “connected”, “coupled” or “joined” to another component, the former may be directly “connected”, “coupled”, and “joined” to the latter or “connected”, “coupled”, and “joined” to the latter via another component.

Repeated descriptions of a component may be omitted or simplified. Unless disclosed to the contrary, the description of any aspect, component, or method may be applied to various embodiments, and repeated descriptions thereof may be omitted or simplified.

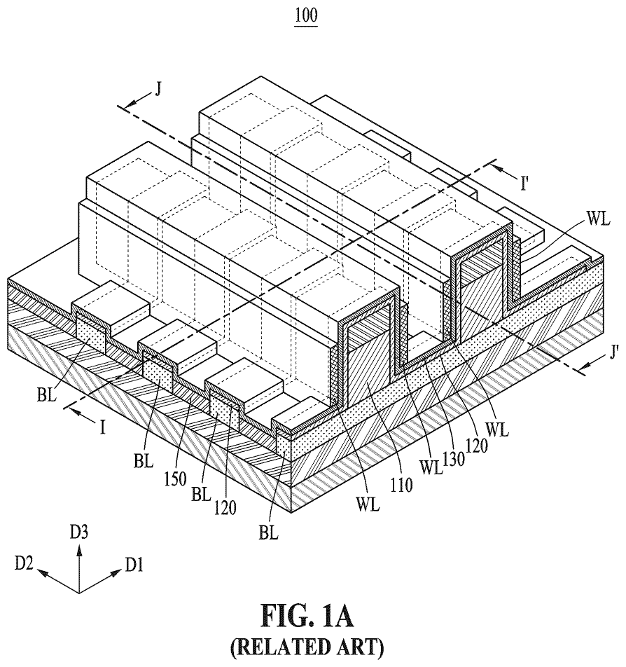

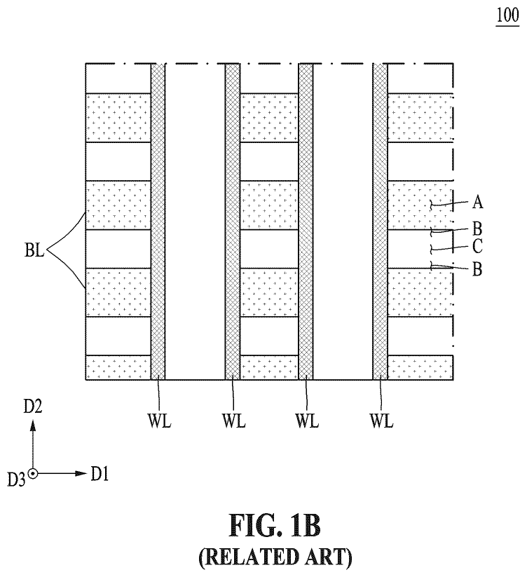

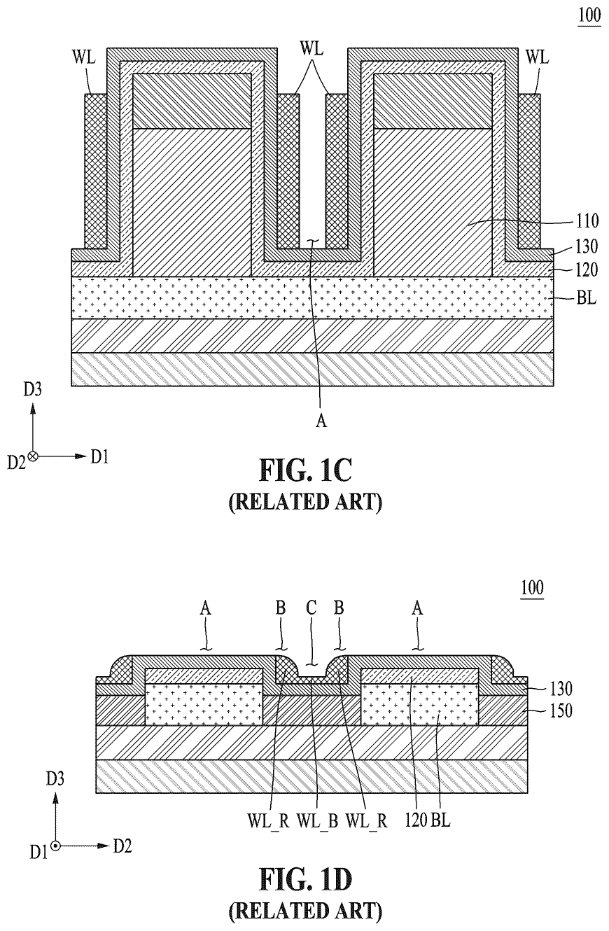

FIG. 1A, FIG. 1B, FIG. 1C, and FIG. 1D illustrate a conventional semiconductor device. FIG. 1A is a perspective view of a conventional semiconductor device. FIG. 1B is a top view of the semiconductor device of FIG. 1A. FIG. 1C is a cross-sectional view taken along line I-I′ of FIG. 1A. FIG. 1D is a cross-sectional view taken along line J-J′ of FIG. 1A.

Referring to FIG. 1A, in a conventional semiconductor device 100, a bit line BL may extend in a first direction D1, and a word line WL may extend in a second direction D2 crossing the first direction D1.

Referring to FIGS. 1B to 1D, a space may be formed between word lines WL adjacent to each other by etching a material used to form word lines WL.

Due to a process of forming the space between word lines WL adjacent to each other, a material used to form a word line WL may not be present in an upper surface portion A of a cover insulating layer 130 that covers a bit line BL, where the upper surface portion A is outside a gate isolation insulating layer 110.

However, word line residues WL_R and a word line bridge WL_B may be formed in portions between bit lines BL adjacent to each other, that is, at portions in which a bit line BL is not disposed.

Specifically, a bit line isolation insulating layer 150 may be disposed between bit lines BL adjacent to each other. The cover insulating layer 130 may be disposed on the bit line isolation insulating layer 150. The word line residuals WL_R may remain in regions B adjacent to bit lines BL in an upper surface portion of the cover insulating layer 130 that covers the bit line isolation insulating layer 150. The word line residuals WL_R between bit lines BL may be connected to each other by the word line bridge WL_B. The word line bridge WL_B may be in a central region C in the upper surface portion of the cover insulating layer 130 that covers the bit line isolation insulating layer 150.

When the word line bridge WL_B is formed, a smooth flow of current between a source and a drain may be inhibited, which may cause a problem in an operation of a transistor. In a process of manufacturing a conventional semiconductor device, a step may be generated between a bit line BL and the bit line isolation insulating layer 150, which may enable the word line residues WL_R and the word line bridge WL_B to be formed. For example, in a process of performing etching to form a plurality of gate isolation insulating layers 110, and a process of performing etching to form a channel layer 120 on a bit line BL, the step may be generated.

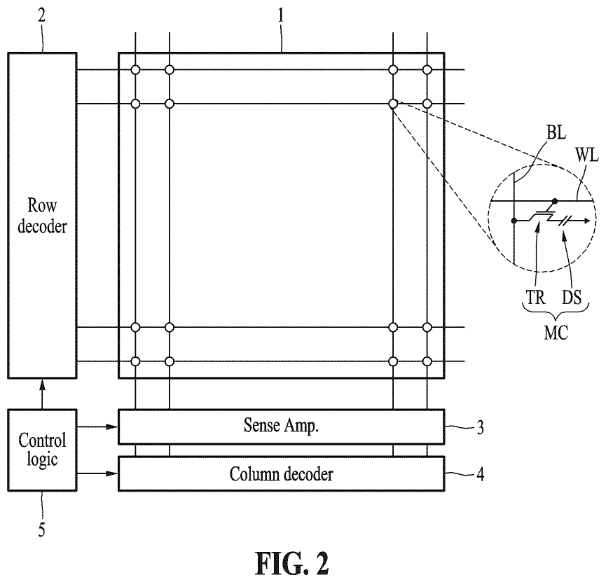

FIG. 2 is a block diagram illustrating a semiconductor memory device with a semiconductor device according to an embodiment.

The semiconductor memory device may include a memory cell array 1, a row decoder 2, a sense amplifier 3 (sense amp.), a column decoder 4, and a control logic 5. For example, the semiconductor memory device may be implemented as a dynamic random access memory (DRAM) device.

The memory cell array 1 may include a plurality of memory cells MC. The plurality of memory cells MC may be two-dimensionally or three-dimensionally arranged. For example, the memory cell array 1 may be disposed on a surface of a substrate, and a plane of the memory cell array 1 may be parallel to a plane of the substrate. Each of the memory cells MC may be connected to a word line WL and a bit line BL that cross each other.

Each of the memory cells MC may include a selection element TR and a data storage element DS. The selection element TR and the data storage element DS may be electrically connected to each other. The selection element TR may be connected to both the word line WL and the bit line BL. For example, the selection element TR may be provided at a position at which the word line WL and the bit line BL cross each other. The selection element TR may include, for example, a field effect transistor (FET). The data storage element DS may include, for example, a capacitor, a magnetic tunnel junction pattern, or a variable resistor. For example, the selection element TR may be a transistor, and the transistor may include a gate electrode that is connected the word line WL, a source terminal connected to one of the bit line BL or the data storage element DS, and a drain terminal connected to the other of the bit line BL or the data storage element DS not connected to the source terminal.

A selection element TR of each of the memory cells MC may include a vertical channel transistor (VCT). A lengthwise direction of a channel of the vertical channel transistor (VCT) may be perpendicular to a surface (e.g., a top surface) of the substrate. A data storage element DS of each of the memory cells MC may include a data storage pattern DSP.

The row decoder 2 may decode an address that is input from the outside of the semiconductor memory device. The row decoder 2 may select a word line WL of the memory cell array 1, based on a result obtained by decoding the address. The result (e.g., the decoded address) obtained by decoding the address in the row decoder 2 may be provided to a row driver (not shown). The row driver may separately provide predetermined voltages to the selected word line WL and unselected word lines, in response to control signals of control circuits.

The sense amplifier 3 may sense, amplify, and output a difference in voltage between a reference bit line and a bit line BL that is selected based on an address decoded by the column decoder 4.

The column decoder 4 may provide a data transmission path between the sense amplifier 3 and an external device (e.g., a memory controller). The column decoder 4 may decode an externally input address to select a bit line BL.

The control logic 5 may generate a control signal that may be used to control an operation of writing or reading data to or from a corresponding memory cell in the memory cell array 1.

For reference, the row decoder 2, the sense amplifier 3, the column decoder 4, and the control logic 5 are illustrated around the memory cell array 1, however, embodiments are not limited thereto. For example, a peripheral circuit including the row decoder 2, the sense amplifier 3, the column decoder 4, and the control logic 5 may be disposed on a plane different from a plane on which the memory cell array 1 is disposed. The peripheral circuit may be disposed above or below the memory cell array 1, for example, using a cell over peripheral (COP) structure. In an example, the peripheral circuit may be provided on the substrate, and the memory cell array 1 may be provided on the peripheral circuit. In another example, the peripheral circuit may be provided on a first substrate, and the memory cell array 1 may be provided on a second substrate. In this example, the first substrate and the second substrate may face each other.

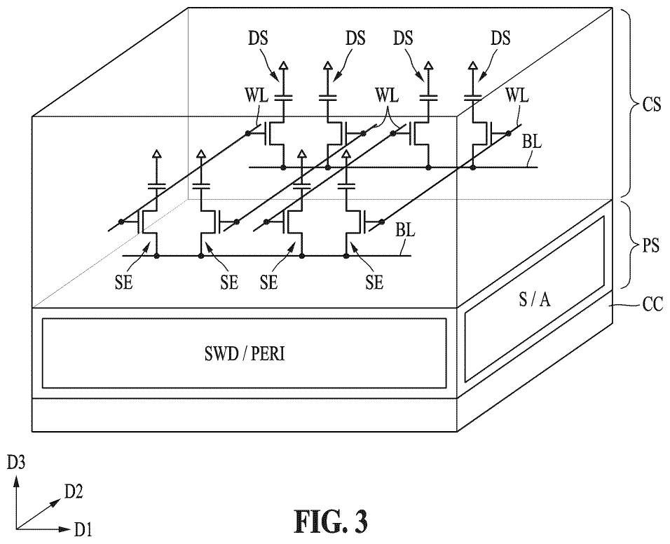

FIG. 3 is a circuit diagram schematically illustrating a semiconductor memory device with a semiconductor device according to an embodiment.

Referring to FIG. 3, the semiconductor memory device with the semiconductor device may include a peripheral circuit structure PS, a substrate CC, and a cell array structure CS. The peripheral circuit structure PS may be disposed on a substrate CC. The cell array structure CS may be disposed on the peripheral circuit structure PS.

The peripheral circuit structure PS may include core and peripheral circuits that may be formed on the substrate CC. The core and peripheral circuits may include the row decoder 2, the column decoder 4, the sense amplifier 3, and the control logic 5 described with reference to FIG. 2. The peripheral circuit structure PS may be provided between the substrate CC and the cell array structure CS in a third direction D3 perpendicular to a top surface of the substrate CC.

For reference, the first direction D1 and the second direction D2 may be directions parallel to the top surface of the substrate CC and perpendicular to each other. The third direction D3 may be a direction perpendicular to the first direction D1 and the second direction D2.

The cell array structure CS may include a bit line BL, a word line WL, and memory cells (e.g., the memory cells MC of FIG. 2) at intersections of the bit line BL and the word line WL. The memory cells (e.g., the memory cells MC of FIG. 2) may be two-dimensionally or three-dimensionally arranged on a plane parallel to the top surface of the substrate CC and may extend in the first direction D1 and the second direction D2 that cross each other. Each of the memory cells (e.g., the memory cells MC of FIG. 2) may include a selection element SE and a data storage element DS, as described herein.

Each of the memory cells (e.g., the memory cells MC of FIG. 2) may include a vertical channel transistor (VCT) as a selection element SE. The vertical channel transistor may be a structure in which a channel extends in the third direction D3 perpendicular to the top surface of the substrate CC. In addition, each of the memory cells (e.g., the memory cells MC of FIG. 2) may include a capacitor as a data storage element DS.

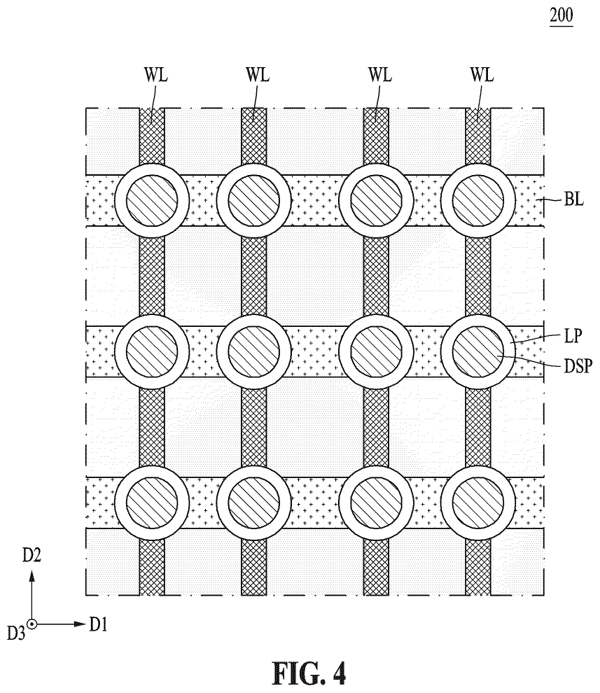

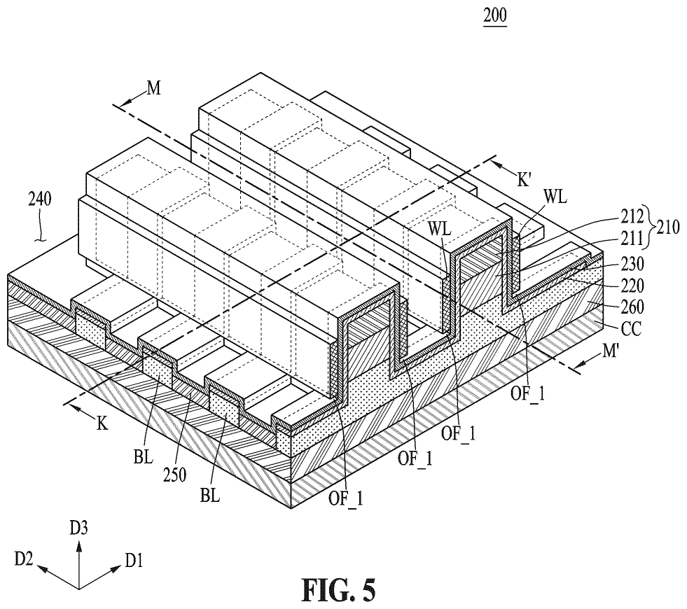

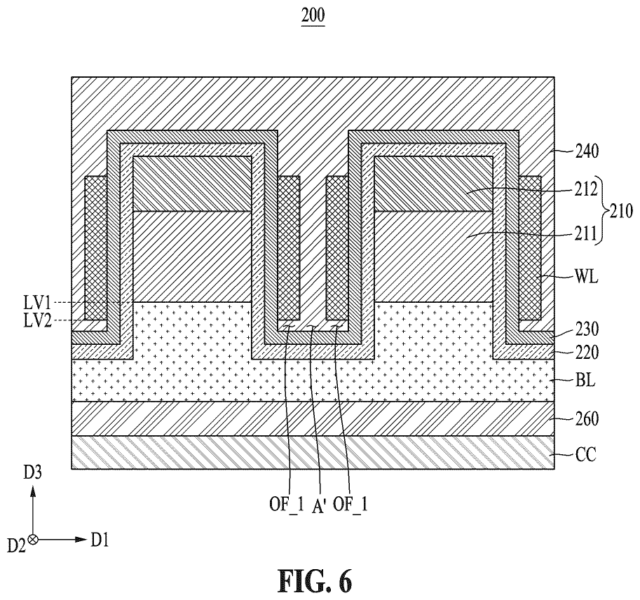

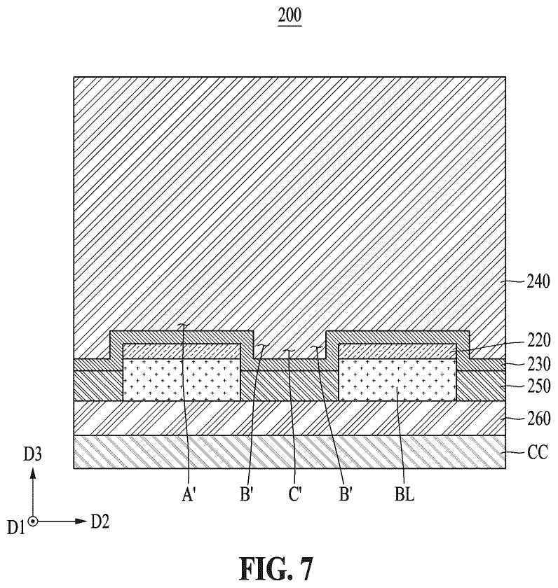

FIG. 4 is a layout diagram illustrating a semiconductor device according to an embodiment. FIG. 5 is a perspective view illustrating a semiconductor device according to an embodiment. FIG. 6 is a cross-sectional view taken along line K-K′ of FIG. 5. FIG. 7 is a cross-sectional view taken along line M-M′ of FIG. 5. The semiconductor device according to an embodiment may include memory cells that include a vertical channel transistor (VCT).

Referring to FIGS. 4 to 7, a semiconductor device 200 may include a substrate CC, a bit line BL, a gate isolation insulating layer 210, a channel layer 220, a cover insulating layer 230, a word line WL, an offset region OF_1, a filling insulating layer 240, a landing pad LP, a data storage pattern DSP, a bit line isolation insulating layer 250, and an insulating film 260. The gate isolation insulating layer 210 may include a first insulating layer 211 and a second insulating layer 212.

The substrate CC may extend in the first direction D1 and the second direction D2. The first direction D1 and the second direction D2 may cross each other and may be parallel to a top surface of the substrate CC. The substrate CC may be a semiconductor substrate. The substrate CC may be a silicon substrate. In an embodiment, the substrate CC may include other materials, such as silicon germanium, indium antimonide, lead telluride compound, indium arsenide, indium phosphide, gallium arsenide, or gallium antimonide, but is not limited thereto.

The bit line BL may be disposed on the substrate CC. The insulating film 260 may be disposed between the substrate CC and the bit line BL. The insulating film 260 may have a peripheral gate structure. The peripheral gate structure may include a peripheral gate insulating film, a peripheral lower conductive pattern, and a peripheral upper conductive pattern. The insulating film 260 may include, for example, at least one of a silicon oxide, a silicon nitride, a silicon oxynitride, or a low-k dielectric material, but is not necessarily limited thereto.

The bit line BL may extend lengthwise in the first direction D1. For example, a plurality of bit lines BL may be disposed on the substrate CC and spaced apart from each other in the second direction D2.

The bit line BL may include, for example, at least one of doped polysilicon, a metal (e.g., Al, Cu, Ti, Ta, Ru, W, Mo, Pt, Ni, or Co), a conductive metal nitride (e.g., TiN, TaN, WN, NbN, TiAlN, TiSiN, TaSiN, or RuTiN), a conductive metal silicide, or a conductive metal oxide (e.g., PtO, RuO₂, IrO₂, SrRuO₃ (SRO), (Ba,Sr)RuO₃ (BSRO), CaRuO₃ (CRO), or LSCo), but is not limited thereto. The bit line BL may include a single layer or multiple layers, which may include the materials described herein or combinations thereof. The bit line BL may include a two-dimensional (2D) semiconductor material. For example, the 2D semiconductor material may include graphene or carbon nanotubes, or a combination thereof.

At least a portion of a space between bit lines BL may be filled with the bit line isolation insulating layer 250. The bit line isolation insulating layer 250 may include at least one of a silicon oxide, a silicon oxynitride, or a high-k dielectric material having a dielectric constant greater than that of the silicon oxide. The high-k dielectric material may include, for example, a metal oxide or a metal oxynitride. The high-k dielectric material may include, for example, at least one of SiN, HfO₂, HfSiO, HfSiON, HfTaO, HfTiO, HfZrO, ZrO₂, or Al₂O₃, but is not limited thereto. A height of the bit line isolation insulating layer 250 in the third direction D3 may be less than a height of the bit line BL.

The data storage pattern DSP may be electrically connected to the channel layer 220. The landing pad LP may be disposed between the channel layer 220 and the data storage pattern DSP.

Landing pads LP may have various shapes, for example, a circular shape, an elliptical shape, a rectangular shape, a square shape, a rhombus shape, or a hexagonal shape. The landing pads LP may include a conductive material. The landing pads LP may include, for example, at least one of doped polysilicon, a conductive metal nitride, a conductive metal silicon nitride, a metal carbonitride, a conductive metal silicide, a conductive metal oxide, a 2D material, a metal, or a metal alloy.

Data storage patterns DSP may be disposed on the landing pads LP, respectively. The data storage patterns DSP may be arranged in a form of a matrix in the second direction D2 and the first direction D1. The data storage patterns DSP may completely or partially overlap the landing pads LP in the third direction D3. For example, an area of a data storage pattern DSP in plan view may be less than or equal to an area of a landing pad LP on which the data storage pattern DSP is disposed. The data storage pattern DSP may be in contact with an entirety of a top surface of the landing pad LP or a portion of the top surface of the landing pad LP.

The data storage patterns DSP may be capacitors. The data storage patterns DSP may include capacitor dielectric films interposed between storage electrodes and a plate electrode. The storage electrodes may be in contact with the landing pads LP. In a plan view, the storage electrodes may have various shapes, for example, a circular shape, an elliptical shape, a rectangular shape, a square shape, a rhombus shape, or a hexagonal shape.

In an embodiment, the data storage patterns DSP may be variable resistance patterns. For example, the data storage patterns DSP may be switched between two resistance states by electrical pulses applied to a memory element. For example, the data storage patterns DSP may include phase-change materials having crystalline states that may be changed depending on an amount of current, perovskite compounds, transition metal oxide, magnetic materials, ferromagnetic materials, or an antiferromagnetic material.

The landing pads LP and the data storage patterns DSP are illustrated as being disposed above bit lines BL and word lines WL based on the third direction D3, however, embodiments are not necessarily limited thereto. For example, the landing pads LP and the data storage patterns DSP may be disposed below the bit lines BL and the word lines WL based on the third direction D3.

The gate isolation insulating layer 210 may extend in the second direction D2 crossing the first direction D1. The gate isolation insulating layer 210 may be disposed on the bit lines BL. The gate isolation insulating layer 210 may have a height in the third direction D3 perpendicular to the substrate CC. The third direction D3 may be a direction perpendicular to both the first direction D1 and the second direction D2. For example, a plurality of gate isolation insulating layers 210 may be disposed on the bit lines BL and spaced apart from each other by a predetermined distance.

The gate isolation insulating layer 210 may include the first insulating layer 211 and a second insulating layer 212. The gate isolation insulating layer 210 may include the first insulating layer 211 disposed on the bit line BL and the bit line isolation insulating layer 250, and the second insulating layer 212 disposed on the first insulating layer 211. For example, the first insulating layer 211 may include at least one of a silicon oxide, a silicon nitride, a silicon oxynitride, or a low-k dielectric material, but is not necessarily limited thereto. The second insulating layer 212 may include at least one of a silicon oxide, a silicon oxynitride, or a high-k dielectric material having a dielectric constant greater than that of the silicon oxide. The high-k dielectric material may include, for example, a metal oxide or a metal oxynitride. The high-k dielectric material may include, for example, at least one of SiN, HfO₂, HfSiO, HfSiON, HfTaO, HfTiO, HfZrO, ZrO₂, or Al₂O₃, but is not limited thereto.

The channel layer 220 may extend along a side surface of each gate isolation insulating layer 210 and a top surface of a bit line BL between gate isolation insulating layers 210 adjacent to each other. The channel layer 220 may also extend along a top surface of each gate isolation insulating layer 210. For example, the channel layer 220 may also extend along a top surface of each second insulating layer 212. The channel layer 220 may not be formed on the bit line isolation insulating layer 250 disposed between bit lines BL adjacent to each other, or on a portion of the gate isolation insulating layer 210 disposed above the bit line isolation insulating layer 250.

The channel layer 220 may include one of an indium gallium zinc oxide (IGZO), an indium zinc oxide (IZO) doped with impurities, an indium oxide (InO), a zinc oxide (ZnO), a gallium oxide (GaO), a tin oxide (SnO), an aluminum zinc oxide (AZO), or an indium tin oxide (ITO). In the indium zinc oxide (IZO) doped with impurities, the impurities may include, for example, at least one of magnesium (Mg), strontium (Sr), barium (Ba), scandium (Sc), yttrium (Y), lanthanum (La), titanium (Ti), zirconium (Zr), hafnium (Hf), aluminum (Al), tin (Sn), or tantalum (Ta). Indium (In), gallium (Ga), and zinc (Zn) may be included in the same or different amounts in the IGZO. The channel layer 220 may be a single layer or a plurality of layers, but is not limited thereto.

The cover insulating layer 230 may cover the channel layer 220. The cover insulating layer 230 may also cover portions exposed by the channel layer 220, for example, the gate isolation insulating layer 210 or a bit line isolation insulating layer 250 between bit lines BL adjacent to each other. For example, the cover insulating layer 230 may be disposed directly on the bit line isolation insulating layer 250 disposed between bit lines BL adjacent to each other, or on the portion of the gate isolation insulating layer 210 disposed above the bit line isolation insulating layer 250.

The cover insulating layer 230 may be disposed between the channel layer 220 and the word line WL. The cover insulating layer 230 may include a silicon oxide film, a silicon oxynitride film, or a high-k dielectric insulating film having a dielectric constant greater than that of the silicon oxide film, or a combination thereof. The cover insulating layer 230 may also be formed of an aluminum oxide (ALO). However, embodiments are not necessarily limited thereto.

The word line WL may be disposed on a sidewall of the cover insulating layer 230 disposed on sides each gate isolation insulating layer 210. The word line WL may be disposed between the cover insulating layer 230 and the filling insulating layer 240. The word line WL may extend lengthwise in the second direction D2. Adjacent word lines WL may be spaced apart from each other in the first direction D1. A top surface of the word line WL may be formed at a level lower than a top surface of the filling insulating layer 240 or the cover insulating layer 230. The word line WL may include, for example, at least one of doped polysilicon, a metal (e.g., Al, Cu, Ti, Ta, Ru, W, Mo, Pt, Ni, or Co), a conductive metal nitride (e.g., TiN, TaN, WN, NbN, TiAlN, TiSiN, TaSiN, or RuTiN), a conductive metal silicide, or a conductive metal oxide (e.g., PtO, RuO₂, IrO₂, SrRuO₃ (SRO), (Ba,Sr) RuO₃ (BSRO), CaRuO₃ (CRO), or LSCo), but is not limited thereto. The word line WL may include a single layer or multiple layers including the materials described herein. The word line WL may include a 2D semiconductor material. For example, the 2D semiconductor material may include graphene or carbon nanotube, or a combination thereof.

The filling insulating layer 240 may be disposed on the plurality of gate isolation insulating layers 210 and the word line WL. The filling insulating layer 240 may fill a space between the plurality of gate isolation insulating layers 210. The filling insulating layer 240 may fill a space between the word lines WL adjacent to each other. The filling insulating layer 240 may also fill the offset region OF_1. The filling insulating layer 240 may include, for example, at least one of a silicon oxide, a silicon nitride, a silicon oxynitride, or a low-k dielectric material, but is not necessarily limited thereto.

A bottom surface of the word line WL may be spaced apart from a top surface of the cover insulating layer 230 between gate isolation insulating layers 210 adjacent to each other. The offset region OF_1 may be formed between the bottom surface of the word line WL and the top surface of the cover insulating layer 230 between the gate isolation insulating layers 210 adjacent to each other. By the offset region OF_1, the bottom surface of the word line WL may be spaced apart from the top surface of the cover insulating layer 230. The filling insulating layer 240 may be disposed in the offset region OF_1. For example, the offset region OF_1 may be filled with the filling insulating layer 240. A top surface of the offset region OF_1 may be formed as a horizontal surface. The offset region OF_1 may be formed by a method of manufacturing a semiconductor device described herein.

Referring to FIG. 5, a plurality of bit lines BL may be disposed on the substrate CC and extending in a first direction and a plurality of gate isolation insulating layers 210 may disposed on the bit lines BL and extending in a second direction crossing the first direction and standing in a third direction. Further, a channel layer 220 may extend along a side surface of the gate isolation insulating layers 210 and top surfaces of bit lines BL between gate isolation insulating layers 210 adjacent to each other. The channel layer 220 may include a plurality of portions extending along each side surface of the gate isolation insulating layers 210 and the top surfaces of bit lines BL between gate isolation insulating layers 210 adjacent to each other. For example, a portion of the channel layer 220 may extend along a side surface of a gate isolation insulating layer 210 and a top surface of a bit line BL between the gate isolation insulating layer 210 and an adjacent gate isolation insulating layer. A plurality of word lines WL may be disposed on sidewalls of the cover insulating layers 230 disposed on sides the gate isolation insulating layers 210. The plurality of word lines WL may have a planar top surface and a planar bottom surface disposed opposite and parallel to the top surface. For example, a height of the word line WL above the cover insulating layers 230 may vary along a length of the word line WL. For example, a first height of the word line WL above the cover insulating layers 230 disposed on the bit line BL may be less than a second height of the word line WL above the cover insulating layer 230.

Referring to FIG. 7, in the semiconductor device 200 having the structure described herein, a material used to form a word line WL may not be present at an upper surface portion A′ of the cover insulating layer 230 that covers a portion of the bit line BL outside the gate isolation insulating layer 210. Word lines WL adjacent to each other may be completely separated from each other. A space may be formed between the word lines WL adjacent to each other and at least partially filled with the filling insulating layer 240. In addition, a word line residue and a word line bridge may not be present in a portion between bit lines BL adjacent to each other, that is, a portion in which a bit line BL is not formed.

In an embodiment, the bit line isolation insulating layer 250 may be disposed between bit lines BL adjacent to each other. The cover insulating layer 230 may be disposed on the bit line isolation insulating layer 250. A word line residue may not be present in a region B′ adjacent to the bit line BL on an upper surface portion of the cover insulating layer 230 that covers the bit line isolation insulating layer 250. A word line bridge may not be present in a central region C′ on the upper surface portion of the cover insulating layer 230 that covers the bit line isolation insulating layer 250.

In other words, a material forming the word line WL may be present on a side surface of the cover insulating layer 230 above each gate isolation insulating layer 210. The material forming the word line WL may not be present in one or more other portions of the semiconductor device 200. In other words, the material forming the word line WL may be present on only a side surface of the cover insulating layer 230 above each gate isolation insulating layer 210.

In an embodiment, the semiconductor device 200 may effectively inhibit or prevent a word line residue and a word line bridge from being left between bit lines BL adjacent to each other. In addition, electrical characteristics and reliability of the semiconductor device 200 may be improved.

Referring to FIG. 6, a level LV1 of a top surface of a first portion of a bit line BL under the gate isolation insulating layer 210 may be higher in the third direction D3 than a level LV2 of a bottom surface of a word line WL. A thickness of the first portion of the bit line BL under the gate isolation insulating layer 210 may be greater than a thickness of a second portion of the bit line BL outside the gate isolation insulating layer 210. Based on the above structure of the bit line BL, a gate underlap phenomenon of a word line WL may be prevented from occurring in response to a formation of an offset region OF_1.

Hereinafter, repeated descriptions that may be equally applicable in the technical idea described herein may be omitted or simplified, and differences between various other embodiments are mainly described.

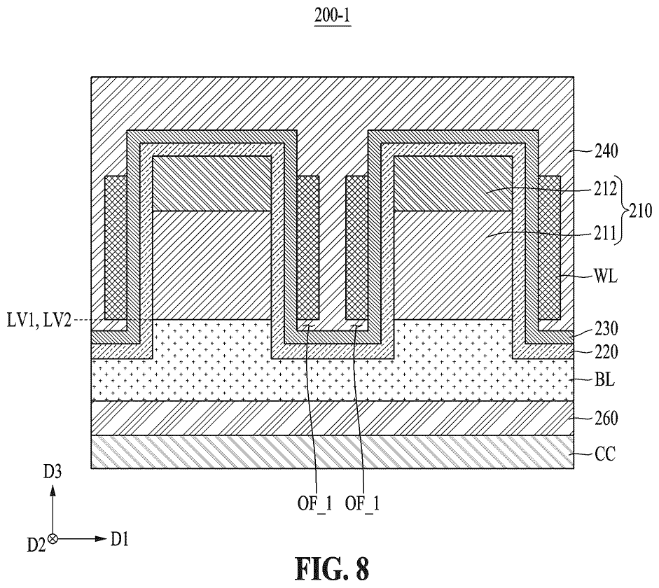

FIG. 8 is a cross-sectional view illustrating an example of a semiconductor device according to an embodiment, taken along line K-K′ of FIG. 5.

Referring to FIG. 8, a level LV1 of a top surface of the first portion of bit line BL under a gate isolation insulating layer 210 of a semiconductor device 200-1 may be equal to a level LV2 of a bottom surface of a word line WL. A thickness of the first portion of the bit line BL under the gate isolation insulating layer 210 may be greater than a thickness of the second portion of the bit line BL outside the gate isolation insulating layer 210.

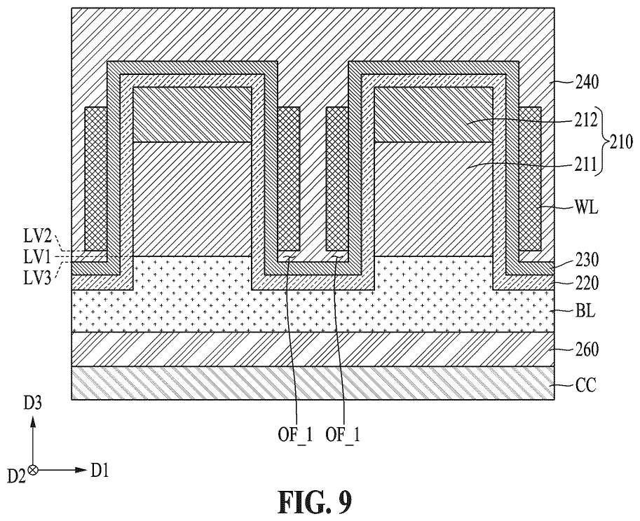

FIG. 9 is a cross-sectional view illustrating another example of a semiconductor device according to an embodiment, taken along line K-K′ of FIG. 5.

Referring to FIG. 9, a level LV1 of a top surface of the first portion of bit line BL under a gate isolation insulating layer 210 of a semiconductor device 200-2 may be lower than a level LV2 of the bottom surface of a word line WL. Here, the level LV1 of the top surface of the first portion of the bit line BL under the gate isolation insulating layer 210 may be higher than a level LV3 of a top surface of a cover insulating layer 230 between gate isolation insulating layers 210 adjacent to each other. The level LV1 of the top surface of the first portion of the bit line BL under the gate isolation insulating layer 210 may be between the level LV2 of the bottom surface of the word line WL and the level LV3 of the top surface of the cover insulating layer 230 between the gate isolation insulating layers 210 adjacent to each other. A thickness of the first portion of the bit line BL under the gate isolation insulating layer 210 may be greater than a thickness of the second portion of the bit line BL outside the gate isolation insulating layer 210.

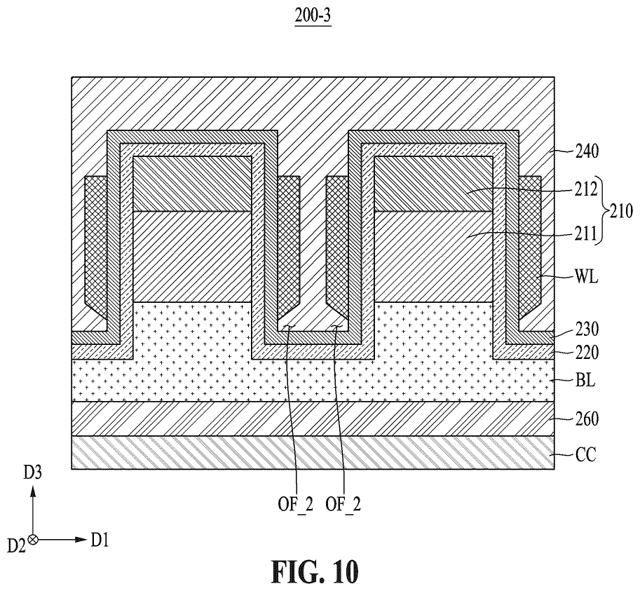

FIG. 10 is a cross-sectional view illustrating another example of a semiconductor device according to an embodiment, taken along line K-K′ of FIG. 5.

Referring to FIG. 10, an upper surface of an offset region OF_2 of a semiconductor device 200-3 may be formed to be inclined. For example, the upper surface of the offset region OF_2 of the semiconductor device 200-3 may be formed to be inclined upward from a cover insulating layer 230 to a filling insulating layer 240. A level of a top surface of the first portion of the bit line BL under a gate isolation insulating layer 210 may be higher than a level of a lowermost surface of a word line WL. However, embodiments are not necessarily limited thereto, and the level of the top surface of the first portion of the bit line BL under the gate isolation insulating layer 210 may be equal to or lower than the level of the lowermost surface of the word line WL.

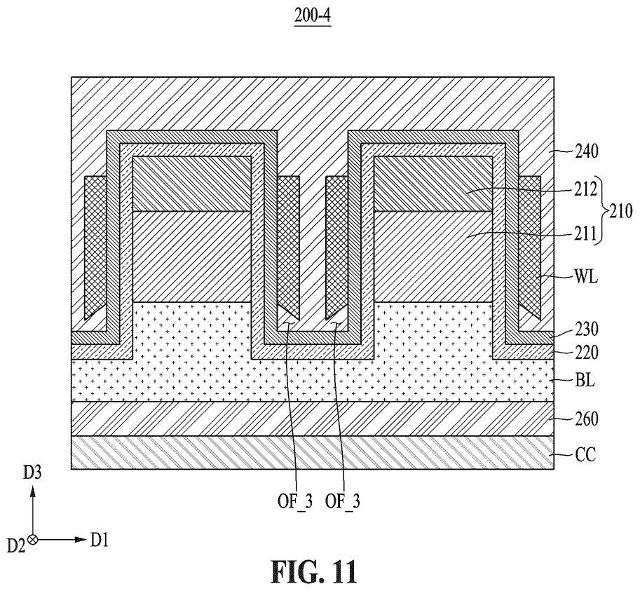

FIG. 11 is a cross-sectional view illustrating another example of a semiconductor device according to an embodiment, taken along line K-K′ of FIG. 5.

Referring to FIG. 11, an upper surface of an offset region OF_3 of a semiconductor device 200-4 may be formed to be inclined. For example, the upper surface of the offset region OF_3 of a semiconductor device 200-4 may be formed to be inclined downward from a cover insulating layer 230 to a filling insulating layer 240. A level of a top surface of the first portion of the bit line BL under a gate isolation insulating layer 210 may be higher than a level of a lowermost surface of a word line WL. However, embodiments are not necessarily limited thereto, and the level of the top surface of the first portion of the bit line BL under the gate isolation insulating layer 210 may be equal to or lower than the level of the lowermost surface of the word line WL.

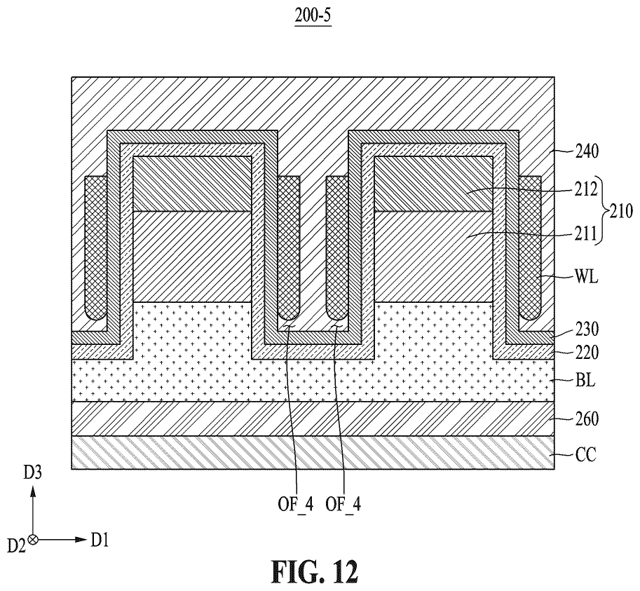

FIG. 12 is a cross-sectional view illustrating another example of a semiconductor device according to an embodiment, taken along line K-K′ of FIG. 5.

Referring to FIG. 12, an upper surface of an offset region OF_4 of a semiconductor device 200-5 may be formed such that a central portion of the upper surface of the offset region OF_4 may be recessed in a rounded shape toward a cover insulating layer 230. A level of a top surface of the first portion of the bit line BL under a gate isolation insulating layer 210 may be higher than a level of a lowermost surface of a word line WL. However, embodiments are not necessarily limited thereto, and the level of the top surface of the first portion of the bit line BL under the gate isolation insulating layer 210 may be equal to or lower than the level of the lowermost surface of the word line WL.

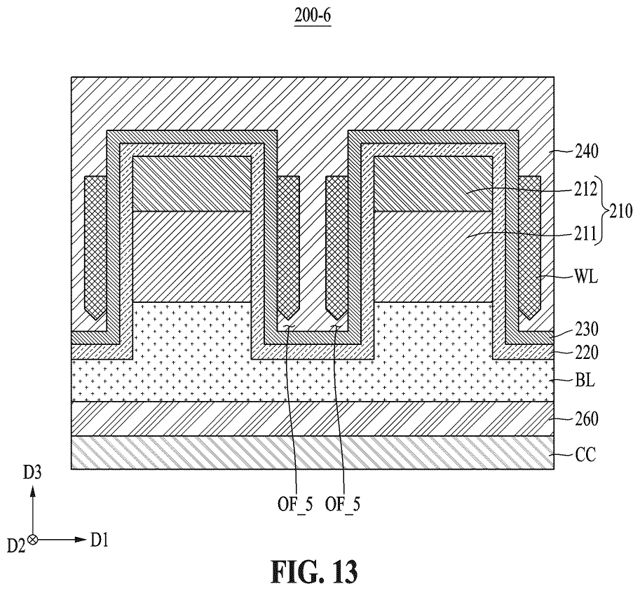

FIG. 13 is a cross-sectional view illustrating another example of a semiconductor device according to an embodiment, taken along line K-K′ of FIG. 5.

Referring to FIG. 13, an upper surface of an offset region OF_5 of a semiconductor device 200-6 may be formed such that a central portion of the upper surface of the offset region OF_5 may be recessed in a shape of a wedge. For example, the upper surface of the offset region OF_5 of the semiconductor device 200-6 may be formed such that the central portion of the upper surface of the offset region OF_5 may be recessed in the shape of a sharp wedge toward a cover insulating layer 230. A level of a top surface of the first portion of the bit line BL under a gate isolation insulating layer 210 may be higher than a level of a lowermost surface of a word line WL. However, embodiments are not necessarily limited thereto, and the level of the top surface of the first portion of the bit line BL under the gate isolation insulating layer 210 may be equal to or lower than the level of the lowermost surface of the word line WL.

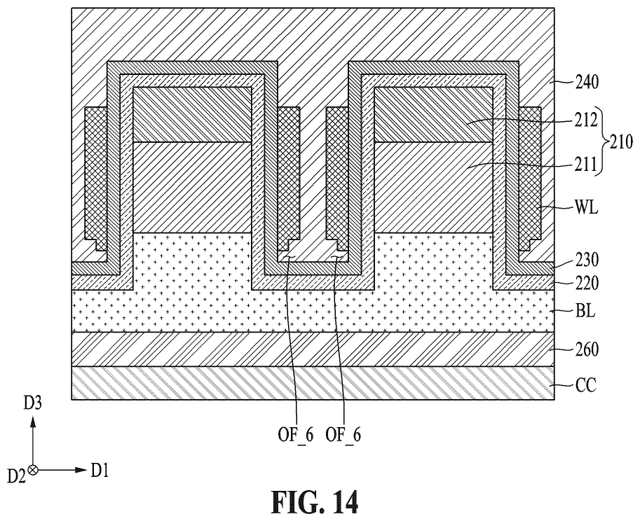

FIG. 14 is a cross-sectional view illustrating another example of a semiconductor device according to an embodiment, taken along line K-K′ of FIG. 5.

Referring to FIG. 14, an upper surface of an offset region OF_6 of a semiconductor device 200-7 may be formed in a stepped shape. For example, the upper surface of the offset region OF_6 of the semiconductor device 200-7 may be formed in a stepped shape ascending from a cover insulating layer 230 toward a filling insulating layer 240. A level of a top surface of the first portion of the bit line BL under a gate isolation insulating layer 210 may be higher than a level of a lowermost surface of a word line WL. However, embodiments are not necessarily limited thereto, and the level of the top surface of the first portion of the bit line BL under the gate isolation insulating layer 210 may be equal to or lower than the level of the lowermost surface of the word line WL.

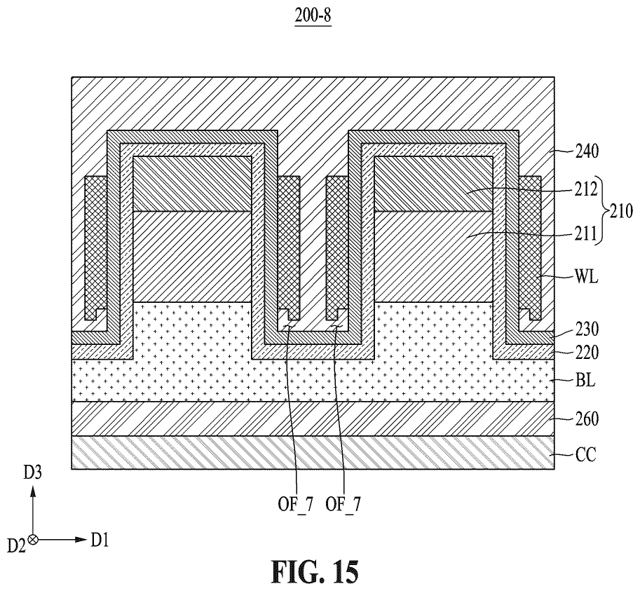

FIG. 15 is a cross-sectional view illustrating another example of a semiconductor device according to an embodiment, taken along line K-K′ of FIG. 5.

Referring to FIG. 15, an upper surface of an offset region OF_7 of a semiconductor device 200-8 may be formed in a stepped shape descending from a cover insulating layer 230 toward a filling insulating layer 240. A level of a top surface of a first portion of a bit line BL under a gate isolation insulating layer 210 may be higher than a level of a lowermost surface of a word line WL. However, embodiments are not necessarily limited thereto, and the level of the top surface of the first portion of the bit line BL under the gate isolation insulating layer 210 may be equal to or lower than the level of the lowermost surface of the word line WL.

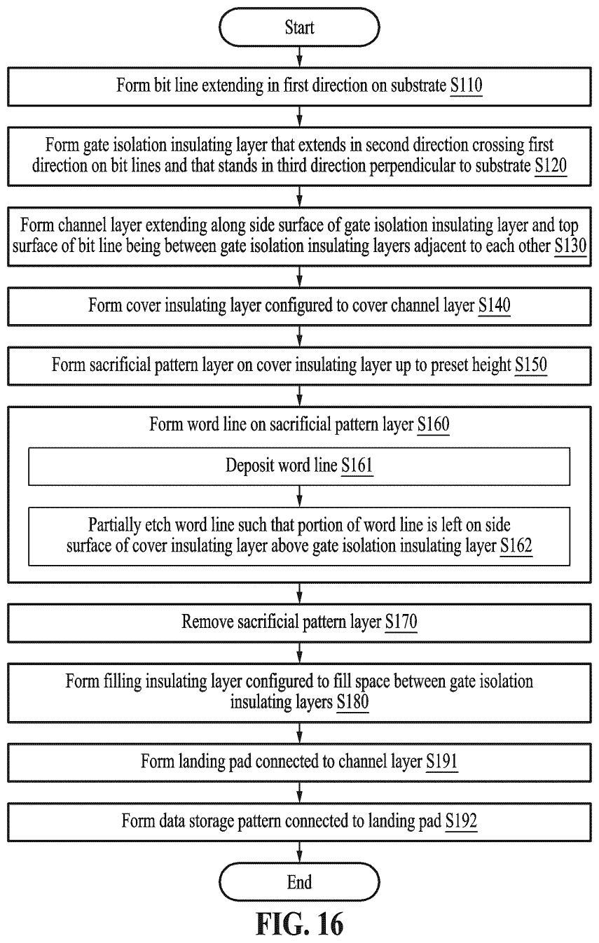

FIG. 16 is a flowchart illustrating a method of manufacturing a semiconductor device according to an embodiment.

Referring to FIG. 16, a method of manufacturing a semiconductor device according to an embodiment may include operation S110 of forming a bit line extending in a first direction on a substrate, the bit line being formed in plurality, operation S120 of forming a gate isolation insulating layer that extends in a second direction crossing the first direction on the bit lines and that stands in a third direction perpendicular to the substrate, the gate isolation insulating layer being formed in plurality, operation S130 of forming a channel layer extending along a side surface of the gate isolation insulating layer and a top surface of a bit line between gate isolation insulating layers adjacent to each other, operation S140 of forming a cover insulating layer configured to cover the channel layer, operation S150 of forming a sacrificial pattern layer on the cover insulating layer up to a preset height, operation S160 of forming a word line on the sacrificial pattern layer, operation S170 of removing the sacrificial pattern layer, operation S180 of forming a filling insulating layer configured to fill at least a portion of a space between the plurality of gate isolation insulating layers, operation S191 of forming a landing pad connected to the channel layer, and operation S192 of forming a data storage pattern connected to the landing pad.

Operation S120 may include forming a first insulating layer on a bit line, and forming a second insulating layer on the first insulating layer.

In operation S150, the sacrificial pattern layer may be formed up to a position higher than a top surface of the cover insulating layer that covers a bit line being outside the gate isolation insulating layer. The sacrificial pattern layer may be a spin-on hardmask (SOH). However embodiments are not necessarily limited thereto. The sacrificial pattern layer may function to fill a step formed between a bit line BL and a bit line isolation insulating layer.

In operation S110, a first portion of a bit line under the gate isolation insulating layer may be formed to be thicker than a second portion of a bit line outside the gate isolation insulating layer. In an example, a top surface of the first portion of the bit line under the gate isolation insulating layer may be formed at a position higher than a bottom surface of a word line. In another example, the top surface of the first portion of the bit line under the gate isolation insulating layer may be formed at the same position as the bottom surface of the word line. In another example, the top surface of the first portion of the bit line under the gate isolation insulating layer may be formed at a position lower than the bottom surface of the word line, and higher than a top surface of a cover insulating layer disposed between gate isolation insulating layers adjacent to each other.

Operation S160 may include operation S161 of depositing the word line, and operation S162 of partially etching the word line such that a portion of the word line is left on a side surface of the cover insulating layer above the gate isolation insulating layer.

In operation S170, an offset region may be formed between a bottom surface of a word line and a top surface of a cover insulating layer disposed between gate isolation insulating layers adjacent to each other. The offset region may be formed in a region in which the sacrificial pattern layer is removed. Operation S170 may be performed by various processes. For example, operation S170 may be performed by a SOH ashing process.

An upper surface of an offset region may be formed as a horizontal surface, an inclined surface, a stepped surface, or a surface that is recessed toward the cover insulating layer.

In operation S180, the offset region may have a space at least partially filled with the filling insulating layer.

In operation S150, the sacrificial pattern layer may be formed up to the same level as the top surface of the cover insulating layer that covers the bit line being outside the gate isolation insulating layer. For example, the sacrificial pattern layer may be formed only up to the same level as the top surface of the cover insulating layer that covers the bit line being outside the gate isolation insulating layer.

In operation S110, the bit lines may be formed with a uniform thickness. For example, a first portion of a bit line under a gate isolation insulating layer may be formed to have the same thickness as that of a second portion of a bit line outside the gate isolation insulating layer.

In operation S170, an offset region may not be separately formed between the bottom surface of the word line and the top surface of the cover insulating layer disposed between the gate isolation insulating layers adjacent to each other. For example, the bottom surface of the word line may be in contact with the top surface of the cover insulating layer disposed between the gate isolation insulating layers adjacent to each other.

The technical idea described herein with reference to FIGS. 5 to 15 may equally apply to operations S120, S130, S140, S160, S180, S191, and S192.

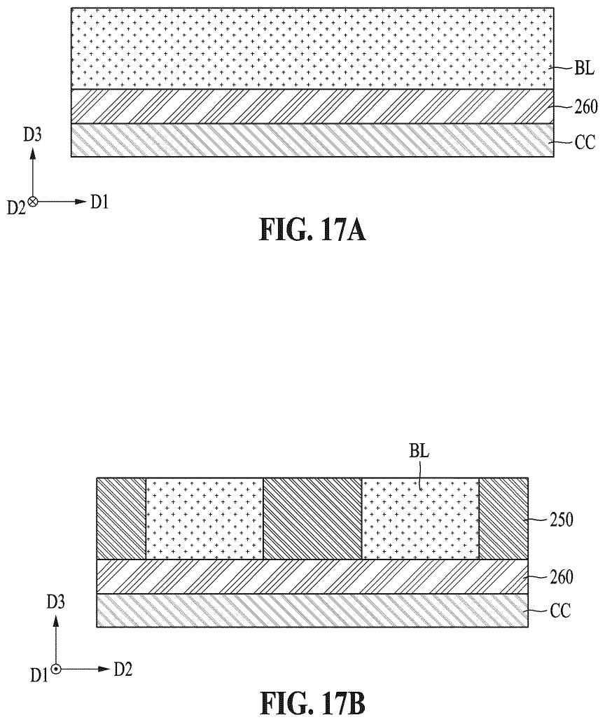

FIGS. 17A to 24B are cross-sectional views to describe an example of a method of manufacturing a semiconductor device. FIGS. 17A, 18A, 19A, 20A, 21A, 22A, 23A, and 24A are cross-sectional views seen in a direction that is the same as or similar to a direction along line K-K′ of FIG. 5. FIGS. 17B, 18B, 19B, 20B, 21B, 22B, 23B, and 24B are cross-sectional views seen in a direction that is the same as or similar to a direction along line M-M′ of FIG. 5.

Referring to FIGS. 17A and 17B, a bit line BL extending in the first direction D1 may be formed on an insulating film 260 on a substrate CC. The bit line BL may be formed to have a preset thickness. A plurality of bit lines BL may be provided and spaced apart from each other in the second direction D2. A space between bit lines BL may be at least partially filled with a bit line isolation insulating layer 250. For example, the bit line isolation insulating layer 250 and another material may fill the space between the bit lines BL. In another example, multiple layers of the bit line isolation insulating layer 250 may fill the space between the bit lines BL.

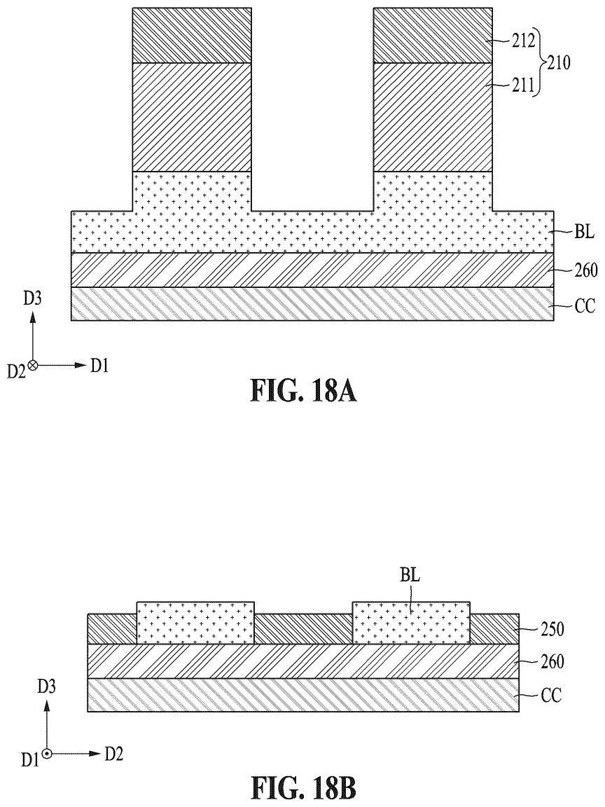

Referring to FIGS. 18A and 18B, a plurality of gate isolation insulating layers 210 may extend in the second direction D2 crossing the first direction D1 on the bit lines BL. The gate isolation insulating layers 210 may stand in the third direction D3 perpendicular to the substrate CC. A gate isolation insulating layer 210 may include a first insulating layer 211 disposed on a bit line BL, and a second insulating layer 212 disposed on the first insulating layer 211. A thickness of the first portion of the bit line BL under a gate isolation insulating layer 210 may be maintained to be greater than a thickness of the second portion of the bit line BL outside the gate isolation insulating layer 210.

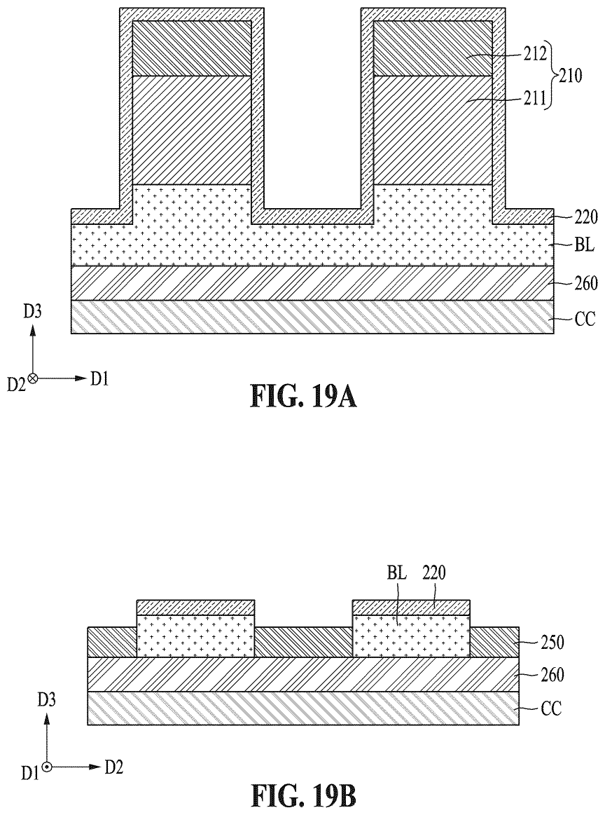

Referring to FIGS. 19A and 19B, a channel layer 220 may be formed along a top surface and a side surface of each gate isolation insulating layer 210 and a top surface of a first portion of a bit line BL between gate isolation insulating layers 210 adjacent to each other. For example, a portion of side surface of the bit line BL may be exposed above the bit line isolation insulating layer 250.

By an etching process performed in a process of forming the plurality of gate isolation insulating layers 210 and the channel layer 220 as described herein, a step may be formed between the bit line BL and the bit line isolation insulating layer 250.

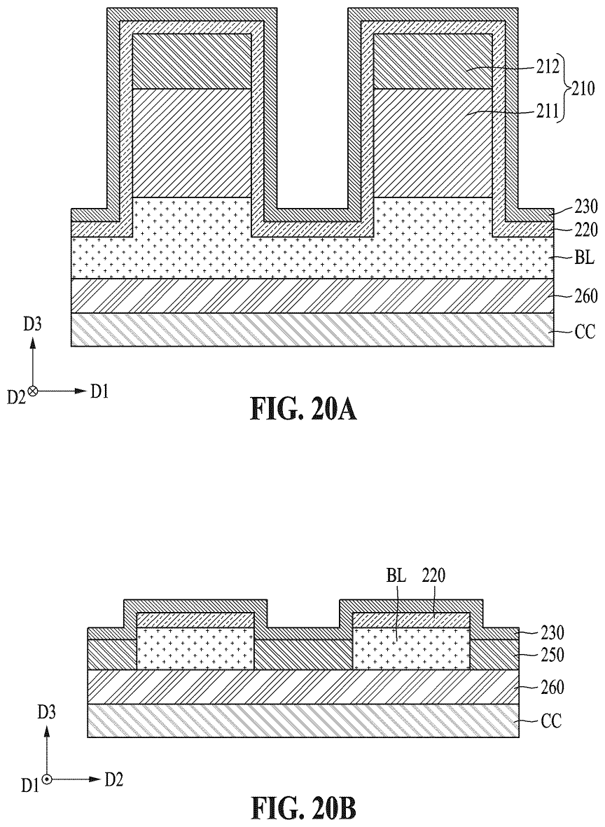

Referring to FIGS. 20A and 20B, a cover insulating layer 230 may be formed to cover the channel layer 220, and portions in which the channel layer 220 is not formed.

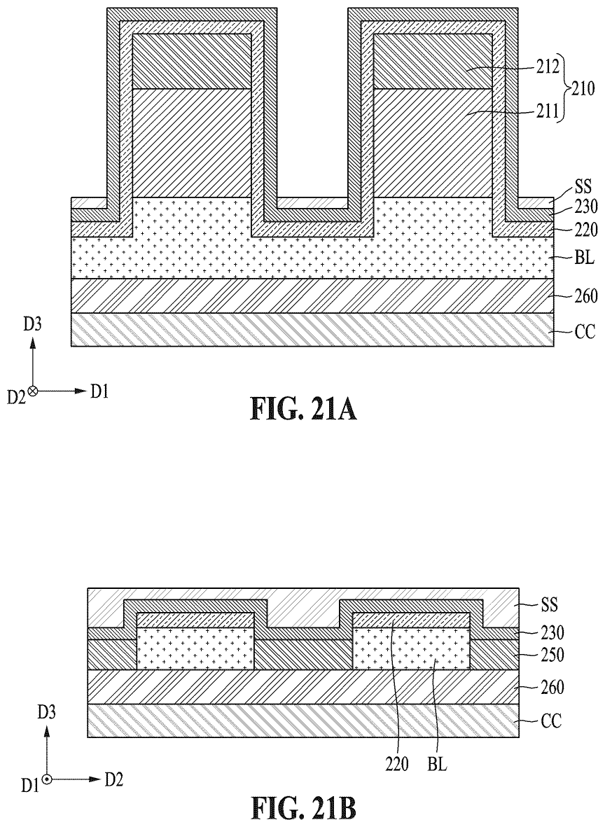

Referring to FIGS. 21A and 21B, a sacrificial pattern layer SS may be formed up to a position higher than a top surface of the cover insulating layer 230 that covers the second portion of the bit line BL outside the gate isolation insulating layer 210. The sacrificial pattern layer SS may function to fill a step formed between a bit line BL and the bit line isolation insulating layer 250.

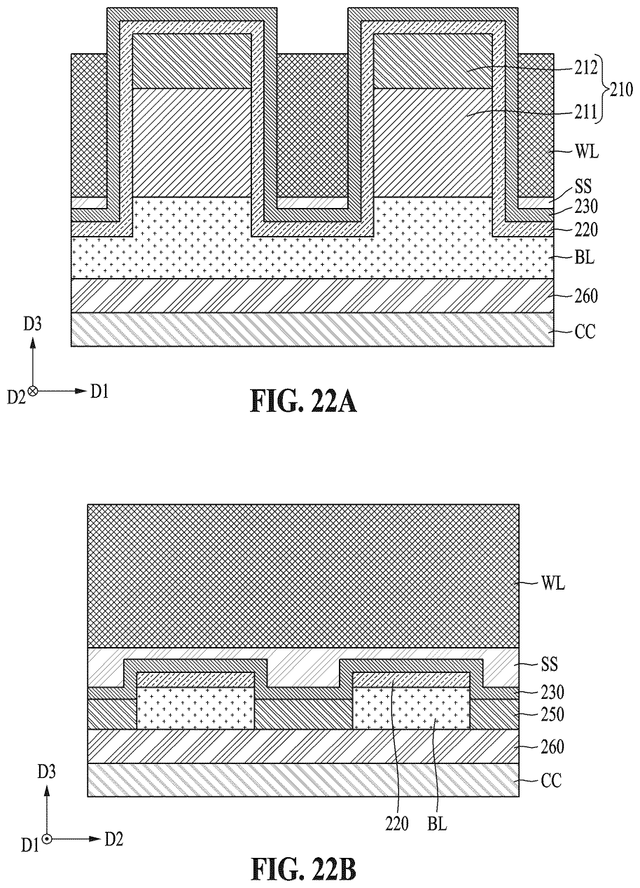

Referring to FIGS. 22A and 22B, a word line WL may be formed on the sacrificial pattern layer SS.

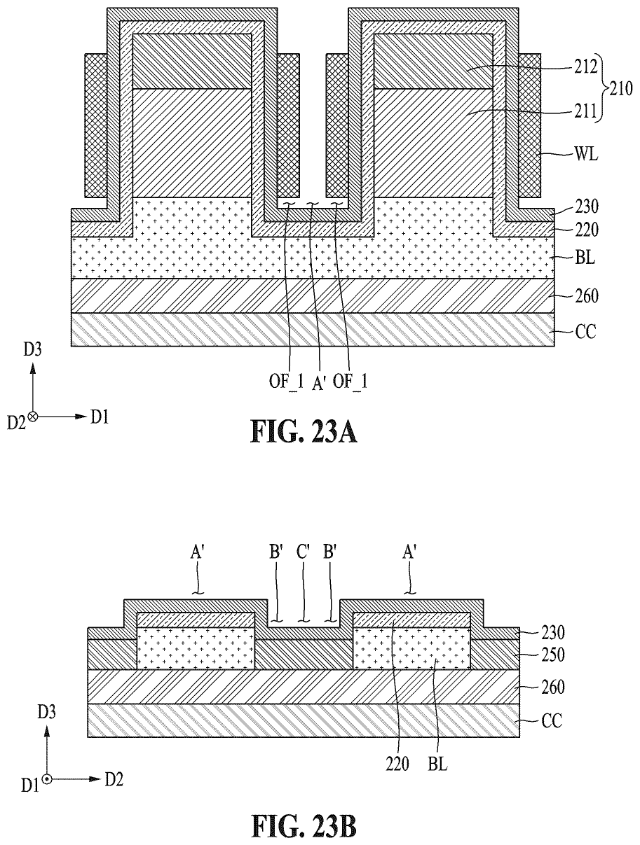

Referring to FIGS. 23A and 23B, the word line WL may be partially etched and removed such that a portion of the word line WL may be left on only a side surface of the cover insulating layer 230 above each gate isolation insulating layer 210. Word lines WL adjacent to each other may be separated from each other, and a space may be formed between the word lines WL adjacent to each other. For example, the word lines WL adjacent to each other may be completely separated from each other, and the space may be formed between the word lines WL adjacent to each other.

The sacrificial pattern layer may be removed following the etching of the word line WL. In a region left by removing the sacrificial pattern layer, an offset region OF_1 may be formed. By the offset region OF_1, a bottom surface of the word line WL may be spaced apart from a top surface of the cover insulating layer 230.

A material used to form the word line WL may not be present in an upper surface portion A′ of the cover insulating layer 230 that covers the second portion of the bit line BL outside the gate isolation insulating layer 210. In addition, a word line residue may not be present in a region B′ adjacent to the bit line BL in an upper surface portion of the cover insulating layer 230 that covers the bit line isolation insulating layer 250. A word line bridge may not be present in a central region C′ in the upper surface portion of the cover insulating layer 230 that covers the bit line isolation insulating layer 250.

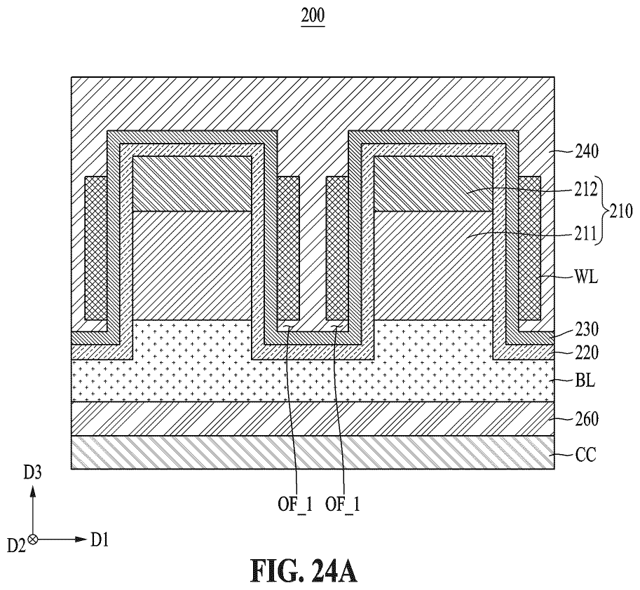

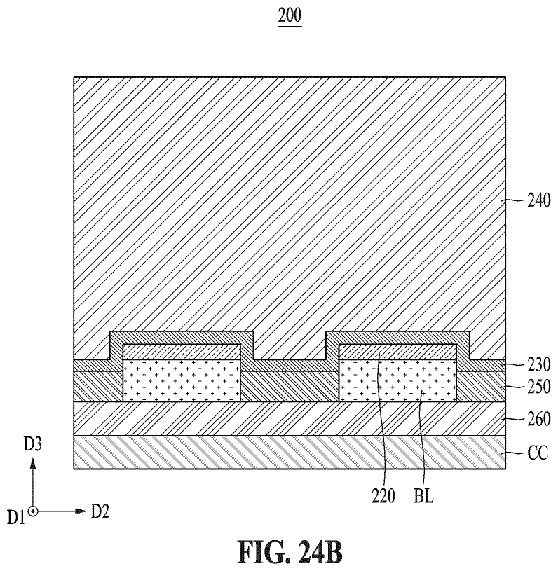

Referring to FIGS. 24A and 24B, a space between the plurality of gate isolation insulating layers 210 may be filled with a filling insulating layer 240. The space between the word lines WL adjacent to each other may be filled with the filling insulating layer 240. The offset region OF_1 may also be filled with the filling insulating layer 240.

In addition, a portion of the channel layer 220 may be exposed by an etching process. In an embodiment, the channel layer 220 and a data storage pattern (not shown) may be electrically connected to each other through a landing pad (not shown).

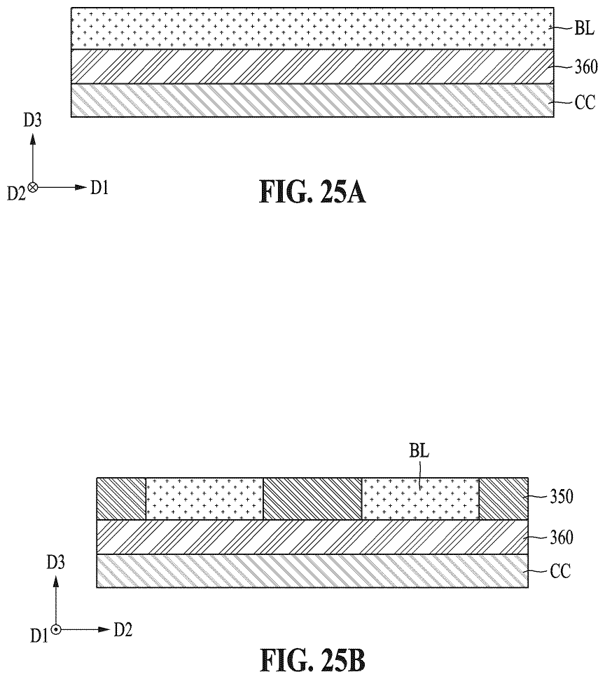

FIGS. 25A to 32B are cross-sectional views to describe another example of a method of manufacturing a semiconductor device. FIGS. 25A, 26A, 27A, 28A, 29A, 30A, 31A, and 32A are cross-sectional views seen in a direction that is the same as or similar to a direction along line K-K′ of FIG. 5. FIGS. 25B, 26B, 27B, 28B, 29B, 30B, 31B, and 32B are cross-sectional views seen in a direction that is the same as or similar to a direction along line M-M′ of FIG. 5.

Referring to FIGS. 25A and 25B, a bit line BL extending in the first direction D1 may be formed on an insulating film 360 disposed on a substrate CC. The bit line BL may be formed at a preset thickness. A plurality of bit lines BL may be provided and spaced apart from each other in the second direction D2. A space between bit lines BL may be at least partially filled with a bit line isolation insulating layer 350.

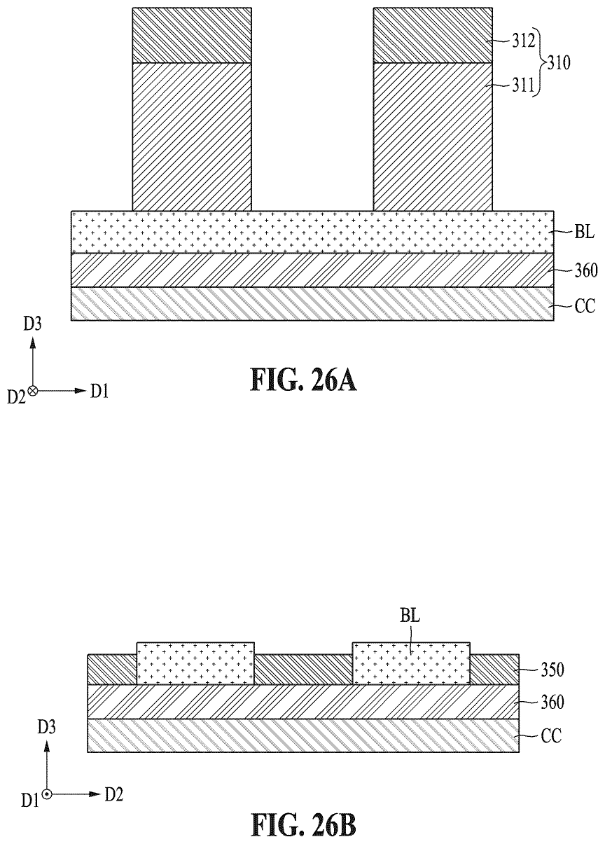

Referring to FIGS. 26A and 26B, a plurality of gate isolation insulating layers 310 may extend in the second direction D2 crossing the first direction D1 on the bit lines BL. The gate isolation insulating layers 310 may stand in the third direction D3 perpendicular to the substrate CC. A gate isolation insulating layers 310 may include a first insulating layer 311 disposed on a bit line BL, and a second insulating layer 312 disposed on the first insulating layer 311. A thickness of a first portion of the bit line BL under a gate isolation insulating layer 310 may be maintained to be the same as a thickness of a second portion of the bit line BL outside the gate isolation insulating layer 310.

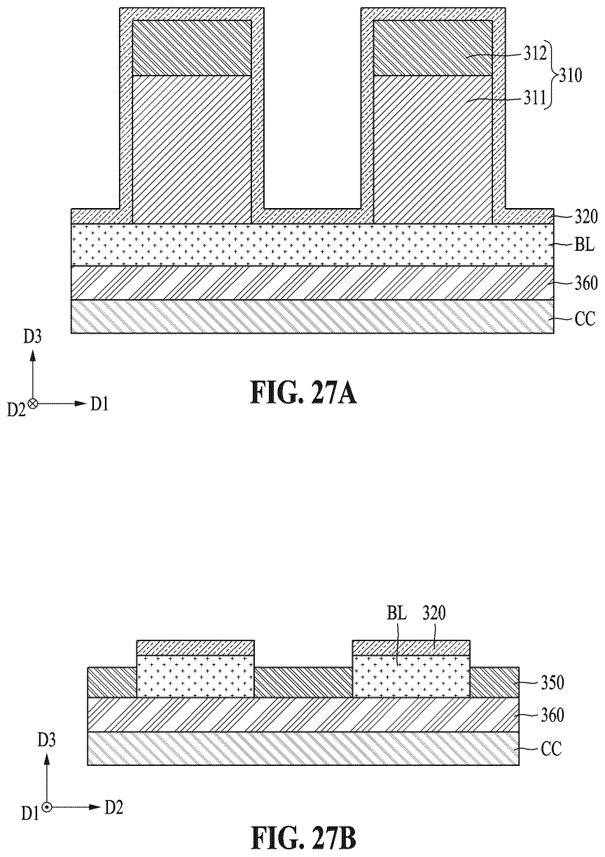

Referring to FIGS. 27A and 27B, a channel layer 320 may be formed along a top surface and a side surface of each gate isolation insulating layer 310, and a top surface of a bit line BL between gate isolation insulating layers 310 adjacent to each other. A portion of a side surface of the bit line BL having a height greater than a height of the bit line isolation insulating layer 350 may be exposed by the channel layer 320.

By an etching process performed in a process of forming the plurality of gate isolation insulating layers 310 and the channel layer 320 as described herein, a step may be formed between the bit line BL and the bit line isolation insulating layer 350.

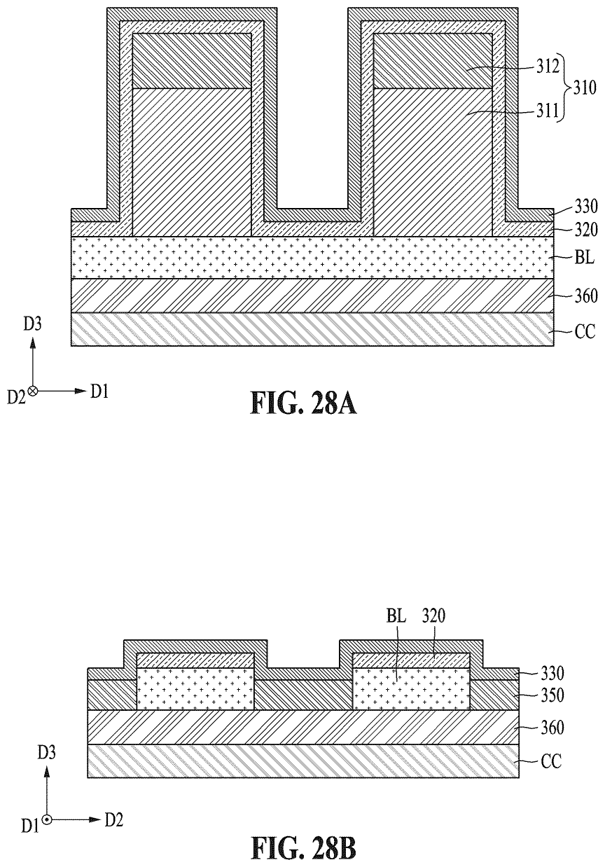

Referring to FIGS. 28A and 28B, a cover insulating layer 330 may be formed to cover the channel layer 320, and portions in which the channel layer 320 is not formed.

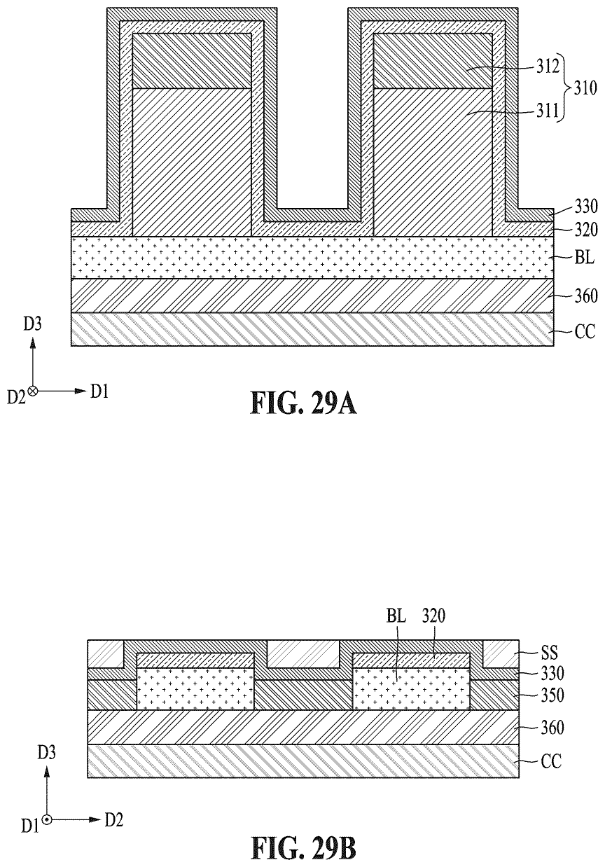

Referring to FIGS. 29A and 29B, a sacrificial pattern layer SS may be formed up to the same level as a top surface of the cover insulating layer 330 that covers the bit line BL outside the gate isolation insulating layer 310. The sacrificial pattern layer SS may function to fill a step formed between a bit line BL and the bit line isolation insulating layer 350.

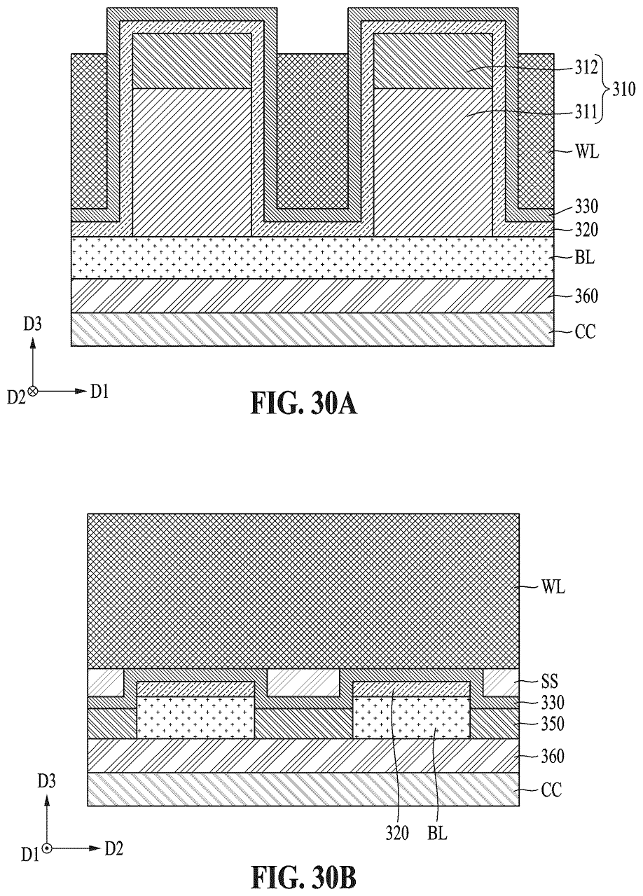

Referring to FIGS. 30A and 30B, a word line WL may be formed on the sacrificial pattern layer SS.

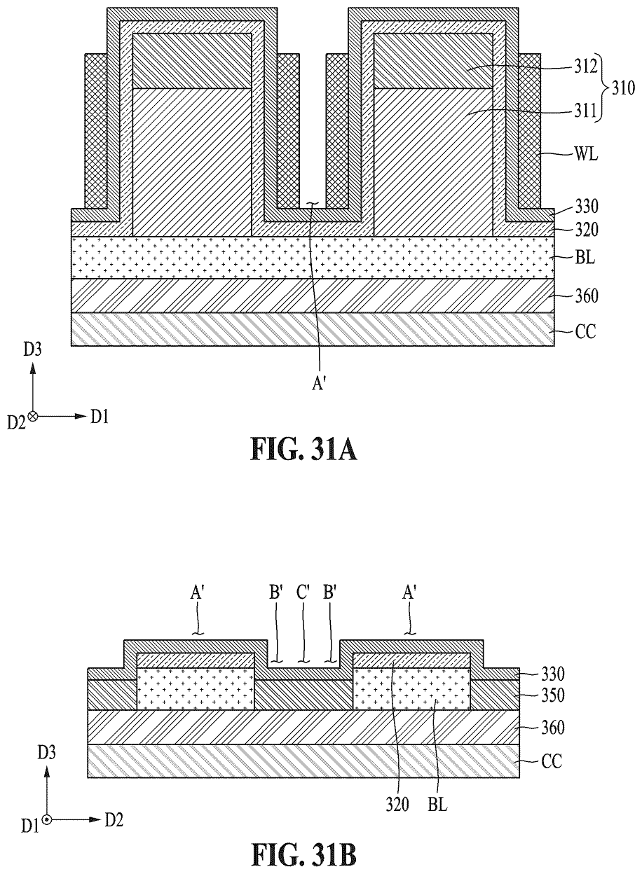

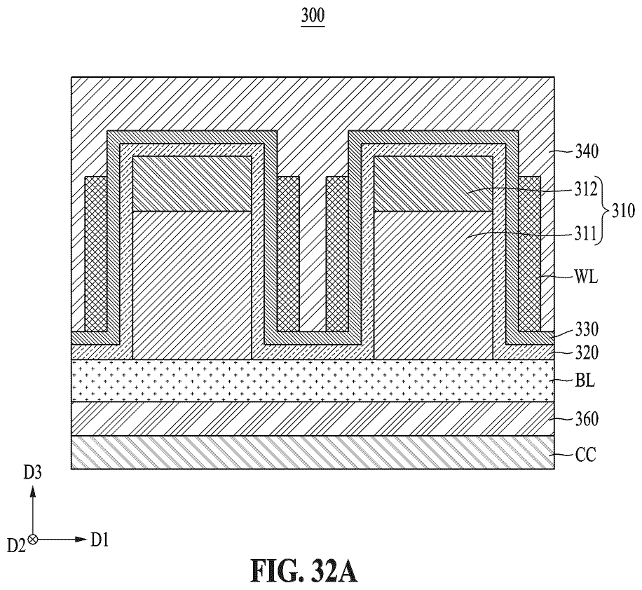

Referring to FIGS. 31A and 31B, the word line WL may be partially etched and removed such that a portion of the word line WL may be left on only a side surface of the cover insulating layer 330 above each gate isolation insulating layer 310. Word lines WL adjacent to each other may be completely separated from each other. For example, the word lines WL adjacent to each other may be completely separated from each other, and a space may be formed between the word lines WL adjacent to each other.

The sacrificial pattern layer may be removed following a partial etching of the word line WL. An offset region may not be separately formed between a bottom surface of the word line WL and a top surface of the cover insulating layer 330 disposed between gate isolation insulating layers 310 adjacent to each other. The bottom surface of the word line WL and the top surface of the cover insulating layer 330 disposed between the gate isolation insulating layers 310 adjacent to each other may be in contact.

A material used to form a word line WL may not be present in an upper surface portion A′ of the cover insulating layer 330 that covers the bit line BL outside the gate isolation insulating layer 310. For example, the upper surface portion A′ of the cover insulating layer 330 that covers the bit line BL outside the gate isolation insulating layer 310 may be exposed by a space between word lines WL that are adjacent to each other. In addition, a word line residue may not be present in a region B′ adjacent to the bit line BL in an upper surface portion of the cover insulating layer 330 that covers the bit line isolation insulating layer 350. A word line bridge may not be present in a central region C′ in the upper surface portion of the cover insulating layer 330 that covers the bit line isolation insulating layer 350.

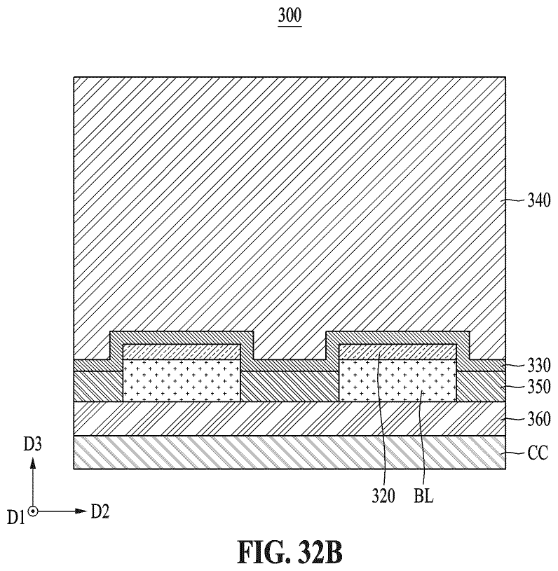

Referring to FIGS. 32A and 32B, a space between the plurality of gate isolation insulating layers 310 may be at least partially filled with a filling insulating layer 340. The space formed between the word lines WL adjacent to each other may be at least partially filled with the filling insulating layer 340. For example, a spacer may be formed of a portion of the filling insulating layer 340 between the word lines WL adjacent to each other.

In addition, a portion of the channel layer 320 may be exposed by an etching process. In an embodiment, the channel layer 320 and a data storage pattern (not shown) may be electrically connected to each other through a landing pad (not shown).

The semiconductor device and the method of manufacturing the semiconductor device according to embodiments may effectively inhibit or prevent a word line residue and a word line bridge from being formed or left between bit lines adjacent to each other.

In addition, the semiconductor device and the method of manufacturing the semiconductor device according to embodiments may effectively prevent a problem from occurring in an operation of a transistor because a smooth flow of current between a source and a drain is impossible when a word line bridge is formed. Furthermore, electrical characteristics and reliability of the semiconductor device may be improved.

While embodiments are described with reference to drawings, it will be apparent to one of ordinary skill in the art that various alterations and modifications in form and details may be made in these embodiments without departing from the spirit and scope of the claims and their equivalents. For example, suitable results may be achieved if the described techniques are performed in a different order and/or if components in a described system, architecture, device, or circuit are combined in a different manner and/or replaced or supplemented by other components or their equivalents.

What is claimed is:

1. A semiconductor device including a vertical channel transistor comprising:
a substrate;
a bit line disposed on the substrate and extending in a first direction;
a gate isolation insulating layer disposed on the bit line and extending in a second direction crossing the first direction and standing in a third direction perpendicular to the substrate;
a channel layer extending along a side surface of the gate isolation insulating layer and a top surface of a bit line between the gate isolation insulating layer and an adjacent gate isolation insulating layer;
a cover insulating layer configured to cover the channel layer; and
a word line disposed on a side surface of the cover insulating layer above the gate isolation insulating layer,
wherein a bottom surface of the word line is spaced apart from a top surface of the cover insulating layer disposed between the gate isolation insulating layer and the adjacent gate isolation insulating layer.

2. The semiconductor device of claim 1, wherein a top surface of a first portion of the bit line under the gate isolation insulating layer is formed at a position higher than the bottom surface of the word line or at a same position as the bottom surface of the word line, or is formed at a position lower than the bottom surface of the word line and higher than the top surface of the cover insulating layer disposed between the gate isolation insulating layer and the adjacent gate isolation insulating layer.

3. The semiconductor device of claim 1, wherein an offset region is formed between the bottom surface of the word line and the top surface of the cover insulating layer disposed between the gate isolation insulating layer and the adjacent gate isolation insulating layer.

4. The semiconductor device of claim 3, wherein an upper surface of the offset region is formed as a horizontal surface, an inclined surface, a stepped surface, or a surface that is recessed toward the cover insulating layer.

5. The semiconductor device of claim 3, further comprising:
a filling insulating layer disposed in a space between the gate isolation insulating layer and the adjacent gate isolation insulating layer,
wherein the filling insulating layer is disposed in the offset region.

6. The semiconductor device of claim 1, wherein the gate isolation insulating layer comprises:
a first insulating layer disposed on the bit line; and
a second insulating layer disposed on the first insulating layer.

7. The semiconductor device of claim 1, further comprising:
a data storage pattern electrically connected to the channel layer; and
a landing pad disposed between the channel layer and the data storage pattern.

8. The semiconductor device of claim 1, further comprising:
an insulating film disposed between the bit line and the substrate.

9. A semiconductor device including a vertical channel transistor comprising:
a substrate;
a bit line disposed on the substrate and extending in a first direction;
a gate isolation insulating layer disposed on the bit line and extending in a second direction crossing the first direction and standing in a third direction;
a channel layer extending along a side surface of the gate isolation insulating layer and a top surface of a bit line between the gate isolation insulating layer and an adjacent gate isolation insulating layer;
a cover insulating layer configured to cover the channel layer;
a filling insulating layer disposed on the cover insulating layer; and
a word line disposed on the filling insulating layer and a side surface of the cover insulating layer above the gate isolation insulating layer,
wherein a bottom surface of the word line is spaced apart from a top surface of the cover insulating layer disposed between the gate isolation insulating layer and the adjacent gate isolation insulating layer.

10. The semiconductor device of claim 9, wherein an offset region is formed between a bottom surface of the word line and the top surface of the cover insulating layer disposed between the gate isolation insulating layer and the adjacent gate isolation insulating layer.

11. The semiconductor device of claim 10, wherein an upper surface of the offset region is formed as a horizontal surface, an inclined surface, a stepped surface, or a surface that is recessed toward the cover insulating layer.

12. A method of manufacturing a semiconductor device, the method comprising:
forming a bit line extending in a first direction on a substrate;
forming a gate isolation insulating layer that extends in a second direction crossing the first direction on the bit line and that stands in a third direction perpendicular to the substrate, the gate isolation insulating layer being disposed adjacent to an adjacent gate isolation insulating layer;
forming a channel layer extending along a side surface of the gate isolation insulating layer and a top surface of the bit line between the gate isolation insulating layer and an adjacent gate isolation insulating layer;
forming a cover insulating layer configured to cover the channel layer;
forming a sacrificial pattern layer on the cover insulating layer;
forming a word line on the sacrificial pattern layer and the cover insulating layer; and
removing the sacrificial pattern layer.

13. The method of claim 12, wherein the forming of the sacrificial pattern layer comprises forming the sacrificial pattern layer up to a same level as a top surface of the cover insulating layer that covers a second portion of the bit line outside the gate isolation insulating layer.

14. The method of claim 13, wherein the forming of the bit line comprises forming the bit line with a uniform thickness.

15. The method of claim 12, wherein the forming of the sacrificial pattern layer comprises forming the sacrificial pattern layer up to a position higher than a top surface of the cover insulating layer that covers a second portion of the bit line outside the gate isolation insulating layer.

16. The method of claim 14, wherein the forming of the bit line comprises forming a first portion of the bit line under the gate isolation insulating layer to be thicker than the second portion of the bit line outside the gate isolation insulating layer.

17. The method of claim 16, wherein a top surface of the first portion of the bit line under the gate isolation insulating layer is formed at a position higher than a bottom surface of the word line or at a same position as the bottom surface of the word line, or is formed at a position lower than the bottom surface of the word line and higher than the top surface of the cover insulating layer disposed between the gate isolation insulating layer and the adjacent gate isolation insulating layer.

18. The method of claim 15, wherein the removing of the sacrificial pattern layer comprises forming an offset region between a bottom surface of the word line and the top surface of the cover insulating layer disposed between the gate isolation insulating layer and the adjacent gate isolation insulating layer.

19. The method of claim 12, wherein the forming of the word line comprises:
depositing a material; and
partially etching the material to form the word line on a side surface of the cover insulating layer above the gate isolation insulating layer.

20. The method of claim 12, further comprising:
forming a filling insulating layer filling a space between a plurality of gate isolation insulating layers including the gate isolation insulating layer;
forming a landing pad connected to the channel layer; and
forming a data storage pattern connected to the landing pad.
